(19) United States
(12) Patent Application Publication
(10) Pub. No.: US 2023/0408931 A1
(43) Pub. Date: Dec. 21, 2023

(54) METHOD OF DETERMINING MARK STRUCTURE FOR OVERLAY FINGERPRINTS

(71) Applicant: ASML NETHERLANDS B.V., Veldhoven (NL)

(72) Inventors: Huaichen ZHANG, Eindhoven (NL); Cyrus Emil TABERY, San Jose, CA (US)

(73) Assignee: ASML NETHERLANDS B.V., Veldhoven (NL)

(21) Appl. No.: 18/035,286

(22) PCT Filed: Nov. 1, 2021
(86) PCT No.: PCT/EP2021/080243

§ 371 Date: May 3, 2023

Related U.S. Application Data
(60) Provisional application No. 63/117,689, filed on Nov. 24, 2020.

(51) Int. Cl. G03F 7/00; H01L 21/66

(52) U.S. Cl. CPC G03F 7/706837; G03F 7/70633; H01L 22/20; G03F 7/70683; G03F 7/70625

(57) ABSTRACT

An apparatus and a method for generating a metrology mark structure that can be formed on a substrate for measuring overlay characteristics induced by one or more processes performed on the substrate by determining features for the metrology mark structure based on a pattern distribution. The method involves obtaining a function to characterize an overlay fingerprint induced by a process performed on a substrate. Based on the function, a pattern distribution is derived, the pattern distribution being indicative of a number of features (e.g., indicative of density) within a portion of the substrate. Based on the pattern distribution, a physical characteristic (e.g., shape, size, etc.) of the features of the metrology mark structure is determined.

### CROSS-REFERENCE TO RELATED APPLICATIONS

This application claims priority of U.S. application 63/117,689 which was filed on Nov. 24, 2020 and which is incorporated herein in its entirety by reference.

### TECHNICAL FIELD

The description herein relates generally to improved metrology systems and methods for overlay measurement in a lithography process and determining process induced overlay fingerprints.

### BACKGROUND

A lithographic projection apparatus can be used, for example, in the manufacture of integrated circuits (ICs). In such a case, a patterning device (e.g., a mask) may contain or provide a pattern corresponding to an individual layer of the IC (“design layout”), and this pattern can be transferred onto a target portion (e.g. comprising one or more dies) on a substrate (e.g., silicon wafer) that has been coated with a layer of radiation-sensitive material (“resist”), by methods such as irradiating the target portion through the pattern on the patterning device. In general, a single substrate contains a plurality of adjacent target portions to which the pattern is transferred successively by the lithographic projection apparatus, one target portion at a time. In one type of lithographic projection apparatuses, the pattern on the entire patterning device is transferred onto one target portion in one go; such an apparatus is commonly referred to as a stepper. In an alternative apparatus, commonly referred to as a step-and-scan apparatus, a projection beam scans over the patterning device in a given reference direction (the “scanning” direction) while synchronously moving the substrate parallel or anti-parallel to this reference direction. Different portions of the pattern on the patterning device are transferred to one target portion progressively. Since, in general, the lithographic projection apparatus will have a reduction ratio M (e.g., 4), the speed F at which the substrate is moved will be 1/M times that at which the projection beam scans the patterning device. More information with regard to lithographic devices can be found in, for example, U.S. Pat. No. 6,046,792, incorporated herein by reference.

Prior to transferring the pattern from the patterning device to the substrate, the substrate may undergo various procedures, such as priming, resist coating and a soft bake. After exposure, the substrate may be subjected to other procedures (“post-exposure procedures”), such as a post-exposure bake (PEB), development, a hard bake and measurement/inspection of the transferred pattern. This array of procedures is used as a basis to make an individual layer of a device, e.g., an IC. The substrate may then undergo various processes such as etching, ion-implantation (doping), metallization, oxidation, chemo-mechanical polishing, etc., all intended to finish off the individual layer of the device. If several layers are required in the device, then the whole procedure, or a variant thereof, is repeated for each layer. Eventually, a device will be present in each target portion on the substrate. These devices are then separated from one another by a technique such as dicing or sawing, whence the individual devices can be mounted on a carrier, connected to pins, etc.

Thus, manufacturing devices, such as semiconductor devices, typically involve processing a substrate (e.g., a semiconductor wafer) using a number of fabrication processes to form various features and multiple layers of the devices. Such layers and features are typically manufactured and processed using, e.g., deposition, lithography, etch, chemical-mechanical polishing, and ion implantation. Multiple devices may be fabricated on a plurality of dies on a substrate and then separated into individual devices. This device manufacturing process may be considered a patterning process. A patterning process involves a patterning step, such as optical and/or nanoimprint lithography using a patterning device in a lithographic apparatus, to transfer a pattern on the patterning device to a substrate and typically, but optionally, involves one or more related pattern processing steps, such as resist development by a development apparatus, baking of the substrate using a bake tool, etching using the pattern using an etch apparatus, etc.

### SUMMARY

With the advancement of lithography and other patterning process technologies, the dimensions of functional elements have continually been reduced while the amount of the functional elements, such as transistors, per device has been steadily increased over decades. In the meanwhile, the requirement of accuracy in terms of overlay, critical dimension (CD), etc. has become more and more stringent. Error, such as error in overlay, error in CD, etc., will inevitably be produced in the patterning process. For example, imaging error may be induced from processes such as patterning, etching, development, baking, chemical mechanical polishing and can be characterized in terms of, e.g., overlay, CD, or other measurable physical characteristics of a pattern. The error may cause a problem in terms of the functioning of the device, including failure of the device to function or one or more electrical problems of the functioning device. Accordingly, it is desirable to be able to characterize one or more of these errors and take steps to design, modify, control, etc. a patterning process to reduce or minimize one or more of these errors.

The present disclosure addresses various problems discussed above. In a first aspect, the present disclosure provides an improved method of determining mark structures for overlay measurements between a first overlay pattern on one layer and a second overlay pattern on another layer in the lithography process. These mark structure may be designed using pattern density maps according to a prescribed overlay characterization, e.g., in terms of an overlay fingerprint potential function. Also, after the mark structure are fabricated by a series of semiconductor processes and measured, overlay contribution from the different processes may be determined by comparing the measurement data with the expected data that is derived according to the prescribed overlay characterization, for example the data being overlay fingerprint data. The overlay measurement may be in micrometer scale, in nanometer scale, or in sub-nanometer scale.

In an embodiment, there is provided a method for determining a metrology mark structure. The method includes obtaining a first function to characterize an overlay fingerprint induced by a semiconductor manufacturing process performed on a substrate. Based on the first function, a pattern distribution indicative of a number of features within a portion of the substrate is derived. Further, using the pattern distribution as a guide, physical characteristics of the features of the metrology mark structure for disposing on the substrate is determined.

In an embodiment, designing a metrology mark structure involves density modulation of features of the metrology structure according to a pattern density map. In an embodiment, top layer features may be aligned to bottom layer features with certain density modulation.

In an embodiment, density modulation can be achieved by varying size, shape, count, etc. of the features or the mark structures. In an embodiment, density modulation is performed based on a pattern density map derived from a specified potential function for which a gradient correspond to an overlay fingerprint. For example, the potential function can be expressed as a convolution of the density function D (characterizing density of features in a pattern) and a kernel function K (characterizing a semiconductor manufacturing process).

The method herein enables measurement of a process performance parameter (e.g., overlay) and enables extraction of process induced fingerprints from the process performance parameter (e.g., overlay fingerprints). In an embodiment, a metrology mark structure may be formed on the substrate extending along an area sufficiently large compared to the length scales of a process effect (e.g., etching loading or stress) of interest with respect to overlay.

According to an embodiment, there is provided a computer program product comprising a non-transitory, computer-readable medium having instructions recorded thereon. The instructions, when executed by a computer, implement the methods listed in the claims.

### BRIEF DESCRIPTION OF THE DRAWINGS

The accompanying drawings, which are incorporated in and constitute a part of this specification, show certain aspects of the subject matter disclosed herein and, together with the description, help explain some of the principles associated with the disclosed embodiments. In the drawings,

FIG. 1 illustrates a lithographic apparatus, according to an embodiment;

FIG. 2 illustrates schematically measurement and exposure processes in the apparatus of FIG. 1, according to an embodiment;

FIG. 3 illustrates a lithographic cell or cluster, according to an embodiment;

FIG. 4 schematically depicts a form of multiple periodic structure target and an outline of a measurement spot on a substrate, according to an embodiment;

FIG. 5 schematically depicts an image of the target of FIG. 4, according to an embodiment;

FIG. 6 schematically depicts an example metrology apparatus and metrology technique, according to an embodiment;

FIG. 7 schematically depicts an example metrology apparatus, according to an embodiment;

FIG. 8 is a flow chart of a method for designing metrology mark structures, according to an embodiment;

FIG. 9 illustrates a process of generating a metrology mark structure from a pattern density map, according to an embodiment;

FIG. 10 illustrates an exemplary metrology mark structure, according to an embodiment;

FIG. 11 illustrates another exemplary metrology mark structure, according to an embodiment;

FIG. 12 illustrates yet another exemplary metrology mark structure, according to an embodiment;

FIG. 13A illustrates an example metrology mark structure, according to an embodiment;

FIG. 13B illustrates a first overlay fingerprint associated with a first process determined using a first kernel applied to the metrology mark structure of FIG. 13A, according to an embodiment;

FIG. 13C illustrates a second overlay fingerprint associated with a second process determined using a second kernel applied to the metrology mark structure of FIG. 13A, according to an embodiment;

FIG. 14 is a block diagram of an example computer system for use in performing some of the methods described herein, according to an embodiment;

FIG. 15 is a schematic diagram of another lithographic projection apparatus (LPA), according to an embodiment;

FIG. 16 is a detailed view of the lithographic projection apparatus, according to an embodiment;

FIG. 17 is a detailed view of source collector module SO of lithographic projection apparatus LPA, according to an embodiment.

### DETAILED DESCRIPTION

The present disclosure will now be described in detail with reference to the drawings, which are provided as illustrative examples of the disclosure so as to enable those skilled in the art to practice the disclosure. Notably, the figures and examples below are not meant to limit the scope of the present disclosure to a single embodiment, but other embodiments are possible by way of interchange of some or all of the described or illustrated elements. Moreover, where certain elements of the present disclosure can be partially or fully implemented using known components, only those portions of such known components that are necessary for an understanding of the present disclosure will be described, and detailed descriptions of other portions of such known components will be omitted so as not to obscure the disclosure. Embodiments described as being implemented in software should not be limited thereto, but can include embodiments implemented in hardware, or combinations of software and hardware, and vice-versa, as will be apparent to those skilled in the art, unless otherwise specified herein. In the present specification, an embodiment showing a singular component should not be considered limiting; rather, the disclosure is intended to encompass other embodiments including a plurality of the same component, and vice-versa, unless explicitly stated otherwise herein. Moreover, applicants do not intend for any term in the specification or claims to be ascribed an uncommon or special meaning unless explicitly set forth as such. Further, the present disclosure encompasses present and future known equivalents to the known components referred to herein by way of illustration.

Although specific reference may be made in this text to the manufacture of ICs, it should be explicitly understood that the description herein has many other possible applications. For example, it may be employed in the manufacture of integrated optical systems, guidance and detection patterns for magnetic domain memories, liquid-crystal display panels, thin-film magnetic heads, etc. The skilled artisan will appreciate that, in the context of such alternative applications, any use of the terms “reticle,” “wafer” or “die” in this text should be considered as interchangeable with the more general terms “mask,” “substrate” and “target portion,” respectively.

In the present document, the terms “radiation” and “beam” used herein encompass all types of electromagnetic radiation, including visible radiation (for example, having a wavelength λ in the range of 400 to 780 nm), ultraviolet (UV) radiation (for example, having a wavelength λ of 365, 248, 193, 157 or 126 nm), extreme ultraviolet (EUV or soft X-ray) radiation (for example, having a wavelength in the range of 5-20 nm such as, for example, 13.5 nm), or hard X-ray working at less than 5 nm, as well as particle beams, such as ion beams or electron beams. Generally, radiation having wavelengths between about 780-3000 nm (or larger) is considered IR radiation. UV refers to radiation with wavelengths of approximately 100-400 nm. Within lithography, the term “UV” also applies to the wavelengths that can be produced by a mercury discharge lamp: G-line 436 nm; H-line 405 nm; and/or, I-line 365 nm Vacuum UV, or VUV (e.g., UV absorbed by air), refers to radiation having a wavelength of approximately 100-200 nm. Deep UV (DUV) generally refers to radiation having wavelengths ranging from 126 nm to 428 nm, and in an embodiment, an excimer laser can generate DUV radiation used within a lithographic apparatus. It should be appreciated that radiation having a wavelength in the range of, for example, 5-20 nm relates to radiation with a certain wavelength band, of which at least part is in the range of 5-20 nm.

The patterning device can comprise, or can form, one or more design layouts. The design layout can be generated utilizing CAD (computer-aided design) programs, this process often being referred to as EDA (electronic design automation). Most CAD programs follow a set of predetermined design rules in order to create functional design layouts/patterning devices. These rules are set by processing and design limitations. For example, design rules define the space tolerance between devices (such as gates, capacitors, etc.) or interconnect lines, so as to ensure that the devices or lines do not interact with one another in an undesirable way. One or more of the design rule limitations may be referred to as “critical dimension” (CD). A critical dimension of a device can be defined as the smallest width of a line or hole or the smallest space between two lines or two holes. Thus, the CD determines the overall size and density of the designed device. Of course, one of the goals in device fabrication is to faithfully reproduce the original design intent on the substrate (via the patterning device).

The term “mask” or “patterning device” as employed in this text may be broadly interpreted as referring to a generic patterning device that can be used to endow an incoming radiation beam with a patterned cross-section, corresponding to a pattern that is to be created in a target portion of the substrate; the term “light valve” can also be used in this context. Besides the classic mask (transmissive or reflective; binary, phase-shifting, hybrid, etc.), examples of other such patterning devices include a programmable mirror array and a programmable LCD array.

An example of a programmable mirror array can be a matrix-addressable surface having a viscoelastic control layer and a reflective surface. The basic principle behind such an apparatus is that (for example) addressed areas of the reflective surface reflect incident radiation as diffracted radiation, whereas unaddressed areas reflect incident radiation as undiffracted radiation. Using an appropriate filter, the said undiffracted radiation can be filtered out of the reflected beam, leaving only the diffracted radiation behind; in this manner, the beam becomes patterned according to the addressing pattern of the matrix-addressable surface. The matrix addressing can be performed using suitable electronic means.

An example of a programmable LCD array is given in U.S. Pat. No. 5,229,872, which is incorporated herein by reference.

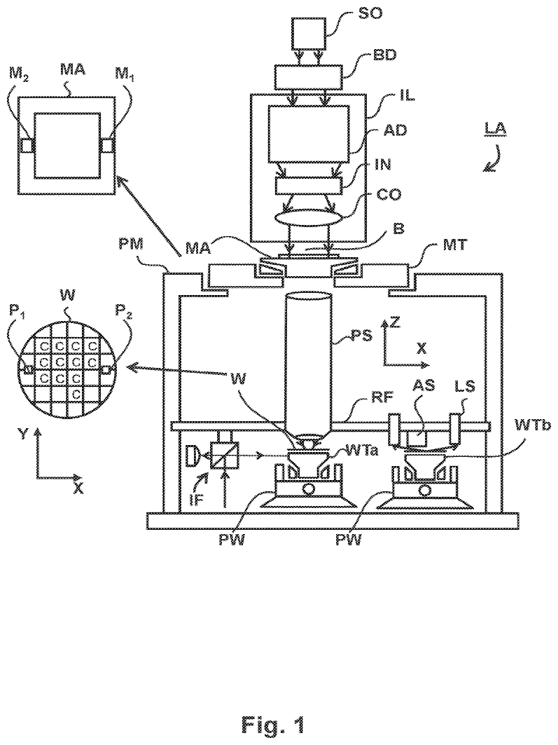

FIG. 1 is schematically a lithographic apparatus. The apparatus includes an illumination system (illuminator) IL configured to condition a radiation beam B (e.g., UV radiation or DUV radiation), a patterning device support or support structure (e.g., a mask table) MT constructed to support a patterning device (e.g., a mask) MA and connected to a first positioner PM configured to accurately position the patterning device in accordance with certain parameters; two substrate tables (e.g., a wafer table) WTa and WTb each constructed to hold a substrate (e.g., a resist coated wafer) W and each connected to a second positioner PW configured to accurately position the substrate in accordance with certain parameters; and a projection system (e.g., a refractive projection lens system) PS configured to project a pattern imparted to the radiation beam B by patterning device MA onto a target portion C (e.g., including one or more dies) of the substrate W. A reference frame RF connects the various components, and serves as a reference for setting and measuring positions of the patterning device and substrate and of features on them.

The illumination system may include various types of optical components, such as refractive, reflective, magnetic, electromagnetic, electrostatic or other types of optical components, or any combination thereof, for directing, shaping, or controlling radiation.

The patterning device support MT holds the patterning device in a manner that depends on the orientation of the patterning device, the design of the lithographic apparatus, and other conditions, such as for example whether or not the patterning device is held in a vacuum environment. The patterning device support can use mechanical, vacuum, electrostatic or other clamping techniques to hold the patterning device. The patterning device support MT may be a frame or a table, for example, which may be fixed or movable as desired. The patterning device support may ensure that the patterning device is at a desired position, for example with respect to the projection system.

The term “patterning device” used herein should be broadly interpreted as referring to any device that can be used to impart a radiation beam with a pattern in its cross-section such as to create a pattern in a target portion of the substrate. It should be noted that the pattern imparted to the radiation beam may not exactly correspond to the desired pattern in the target portion of the substrate, for example if the pattern includes phase-shifting features or so-called assist features. Generally, the pattern imparted to the radiation beam will correspond to a particular functional layer in a device being created in the target portion, such as an integrated circuit.

As here depicted, the apparatus is of a transmissive type (e.g., employing a transmissive patterning device). Alternatively, the apparatus may be of a reflective type (e.g., employing a programmable mirror array of a type as referred to above, or employing a reflective mask). Examples of patterning devices include masks, programmable mirror arrays, and programmable LCD panels. Any use of the terms “reticle” or “mask” herein may be considered synonymous with the more general term “patterning device.” The term “patterning device” can also be interpreted as referring to a device storing in digital form pattern information for use in controlling such a programmable patterning device.

The term “projection system” used herein should be broadly interpreted as encompassing any type of projection system, including refractive, reflective, catadioptric, magnetic, electromagnetic and electrostatic optical systems, or any combination thereof, as appropriate for the exposure radiation being used, or for other factors such as the use of an immersion liquid or the use of a vacuum. Any use of the term “projection lens” herein may be considered as synonymous with the more general term “projection system”.

The lithographic apparatus may also be of a type wherein at least a portion of the substrate may be covered by a liquid having a relatively high refractive index (e.g., water) so as to fill a space between the projection system and the substrate. An immersion liquid may also be applied to other spaces in the lithographic apparatus, for example, between the mask and the projection system. Immersion techniques are well known in the art for increasing the numerical aperture of projection systems.

In operation, the illuminator IL receives a radiation beam from a radiation source SO. The source and the lithographic apparatus may be separate entities, for example when the source is an excimer laser. In such cases, the source is not considered to form part of the lithographic apparatus and the radiation beam is passed from the source SO to the illuminator IL with the aid of a beam delivery system BD including, for example, suitable directing mirrors and/or a beam expander. In other cases, the source may be an integral part of the lithographic apparatus, for example when the source is a mercury lamp. The source SO and the illuminator IL, together with the beam delivery system BD if used, may be referred to as a radiation system.

The illuminator IL may for example include an adjuster AD for adjusting the angular intensity distribution of the radiation beam, an integrator IN and a condenser CO. The illuminator may be used to condition the radiation beam, to have a desired uniformity and intensity distribution in its cross section.

The radiation beam B is incident on the patterning device MA, which is held on the patterning device support MT, and is patterned by the patterning device. Having traversed the patterning device (e.g., mask) MA, the radiation beam B passes through the projection system PS, which focuses the beam onto a target portion C of the substrate W. With the aid of the second positioner PW and position sensor IF (e.g., an interferometric device, linear encoder, 2-D encoder or capacitive sensor), the substrate table WTa or WTb can be moved accurately, e.g., so as to position different target portions C in the path of the radiation beam B. Similarly, the first positioner PM and another position sensor (which is not explicitly depicted in FIG. 1) can be used to accurately position the patterning device (e.g., mask) MA with respect to the path of the radiation beam B, e.g., after mechanical retrieval from a mask library, or during a scan.

Patterning device (e.g., mask) MA and substrate W may be aligned using mask alignment marks M1, M2 and substrate alignment marks P1, P2. Although the substrate alignment marks as illustrated occupy dedicated target portions, they may be located in spaces between target portions (these are known as scribe-lane alignment marks). Similarly, in situations in which more than one die is provided on the patterning device (e.g., mask) MA, the mask alignment marks may be located between the dies. Small alignment marks may also be included within dies, in amongst the device features, in which case it is desirable that the markers be as small as possible and not require any different imaging or process conditions than adjacent features. The alignment system, which detects the alignment markers, is described further below.

The depicted apparatus could be used in a variety of modes. In a scan mode, the patterning device support (e.g., mask table) MT and the substrate table WT are scanned synchronously while a pattern imparted to the radiation beam is projected onto a target portion C (e.g., a single dynamic exposure). The speed and direction of the substrate table WT relative to the patterning device support (e.g., mask table) MT may be determined by the (de-)magnification and image reversal characteristics of the projection system PS. In scan mode, the maximum size of the exposure field limits the width (in the non-scanning direction) of the target portion in a single dynamic exposure, whereas the length of the scanning motion determines the height (in the scanning direction) of the target portion. Other types of lithographic apparatus and modes of operation are possible, as is well-known in the art. For example, a step mode is known. In so-called “maskless” lithography, a programmable patterning device is held stationary but with a changing pattern, and the substrate table WT is moved or scanned.

Combinations and/or variations on the above-described modes of use or entirely different modes of use may also be employed.

Lithographic apparatus LA is of a so-called dual stage type which has two substrate tables WTa, WTb and two stations—an exposure station EXP and a measurement station MEA—between which the substrate tables can be exchanged. While one substrate on one substrate table is being exposed at the exposure station, another substrate can be loaded onto the other substrate table at the measurement station and various preparatory steps carried out. This enables a substantial increase in the throughput of the apparatus. The preparatory steps may include mapping the surface height contours of the substrate using a level sensor LS and measuring the position of alignment markers on the substrate using an alignment sensor AS. If the position sensor IF is not capable of measuring the position of the substrate table while it is at the measurement station as well as at the exposure station, a second position sensor may be provided to enable the positions of the substrate table to be tracked at both stations, relative to reference frame RF. Other arrangements are known and usable instead of the dual-stage arrangement shown. For example, other lithographic apparatuses are known in which a substrate table and a measurement table are provided. These are docked together when performing preparatory measurements, and then undocked while the substrate table undergoes exposure.

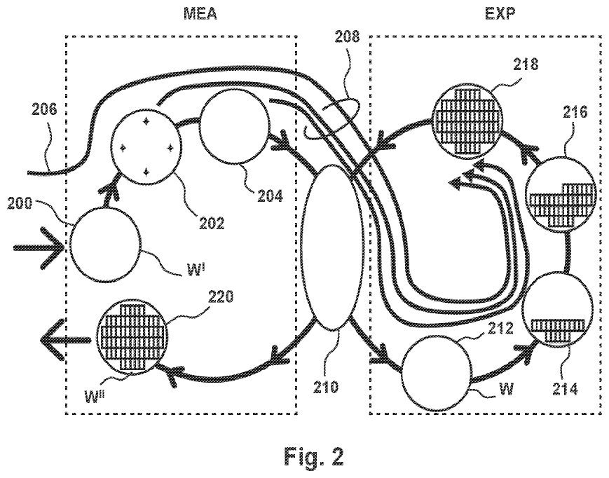

FIG. 2 illustrates exemplary measurement and exposure processes in the apparatus of FIG. 1 which includes the steps to expose target portions (e.g. dies) on a substrate W in the dual stage apparatus of FIG. 1. On the left-handed side within a dotted box steps are performed at a measurement station MEA, while the right-handed side shows steps performed at the exposure station EXP. From time to time, one of the substrate tables WTa, WTb will be at the exposure station, while the other is at the measurement station, as described above. For the purposes of this description, it is assumed that a substrate W has already been loaded into the exposure station. At step 200, a new substrate W′ is loaded to the apparatus by a mechanism not shown. These two substrates are processed in parallel in order to increase the throughput of the lithographic apparatus.

Referring initially to the newly-loaded substrate W′, this may be a previously unprocessed substrate, prepared with a new photoresist for first time exposure in the apparatus. In general, however, the lithography process described will be merely one step in a series of exposure and processing steps, so that substrate W′ has been through this apparatus and/or other lithography apparatuses, several times already, and may have subsequent processes to undergo as well. Particularly for the purpose of improving overlay performance, the task is to ensure that new patterns are applied in the correct position on a substrate that has already been subjected to one or more cycles of patterning and processing. These processing steps progressively introduce distortions in the substrate that can be measured and corrected for to achieve satisfactory overlay performance.

The previous and/or subsequent patterning step may be performed in other lithography apparatuses, as just mentioned, and may even be performed in different types of lithography apparatus. For example, some layers in the device manufacturing process which are very demanding in parameters such as resolution and overlay may be performed in a more advanced lithography tool than other layers that are less demanding. Therefore, some layers may be exposed in an immersion-type lithography tool, while others are exposed in a “dry” tool. Some layers may be exposed in a tool working at DUV wavelengths, while others are exposed using EUV wavelength radiation.

At 202, alignment measurements using the substrate marks P1, etc., and image sensors (not shown) are used to measure and record alignment of the substrate relative to substrate table WTa/WTb. In addition, several alignment marks across the substrate W′ will be measured using alignment sensor AS. These measurements are used in one embodiment to establish a “wafer grid,” which maps very accurately the distribution of marks across the substrate, including any distortion relative to a nominal rectangular grid.

At step 204, a map of wafer height (Z) against the X-Y position is measured also using the level sensor LS. Conventionally, the height map is used only to achieve accurate focusing of the exposed pattern. It may be used for other purposes in addition.

When substrate W′ was loaded, recipe data 206 were received, defining the exposures to be performed, and also properties of the wafer and the patterns previously made and to be made upon it. These recipe data are added to the measurements of wafer position, wafer grid, and height map that were made at 202, 204, and then a complete set of recipe and measurement data 208 can be passed to the exposure station EXP. The measurements of alignment data for example comprise X and Y positions of alignment targets formed in a fixed or nominally fixed relationship to the product patterns that are the product of the lithographic process. These alignment data, taken just before exposure, are used to generate an alignment model with parameters that fit the model to the data. These parameters and the alignment model will be used during the exposure operation to correct positions of patterns applied in the current lithographic step. The model in use interpolates positional deviations between the measured positions. A conventional alignment model might comprise four, five or six parameters, together defining translation, rotation and scaling of the “ideal” grid, in different dimensions. Advanced models are known that use more parameters.

At 210, wafers W′ and W are swapped, so that the measured substrate W′ becomes the substrate W entering the exposure station EXP. In the example apparatus of FIG. 1, this swapping is performed by exchanging the supports WTa and WTb within the apparatus, so that the substrates W, W′ remain accurately clamped and positioned on those supports, to preserve relative alignment between the substrate tables and substrates themselves. Accordingly, once the tables have been swapped, determining the relative position between projection system PS and substrate table WTb (formerly WTa) is all that is necessary to make use of the measurement information 202, 204 for the substrate W (formerly W′) in control of the exposure steps. At step 212, reticle alignment is performed using the mask alignment marks M1, M2. In steps 214, 216, 218, scanning motions and radiation pulses are applied at successive target locations across the substrate W, in order to complete the exposure of a number of patterns.

By using the alignment data and height map obtained at the measuring station, and the performance of the exposure steps, these patterns are accurately aligned with respect to the desired locations, and, in particular, with respect to features previously laid down on the same substrate. The exposed substrate, now labeled W″ is unloaded from the apparatus at step 220, to undergo etching or other processes, in accordance with the exposed pattern.

The skilled person will know that the above description is a simplified overview of a number of very detailed steps involved in one example of a real manufacturing situation. For example, rather than measuring alignment in a single pass, often there will be separate phases of coarse and fine measurement, using the same or different marks. The coarse and/or fine alignment measurement steps can be performed before or after the height measurement, or interleaved.

In one embodiment, optical position sensors, such as alignment sensor AS, use visible and/or near-infra-red (NIR) radiation to read alignment marks. In some processes, processing of layers on the substrate after the alignment mark has been formed leads to situations in which the marks cannot be found by such an alignment sensor due to low or no signal strength.

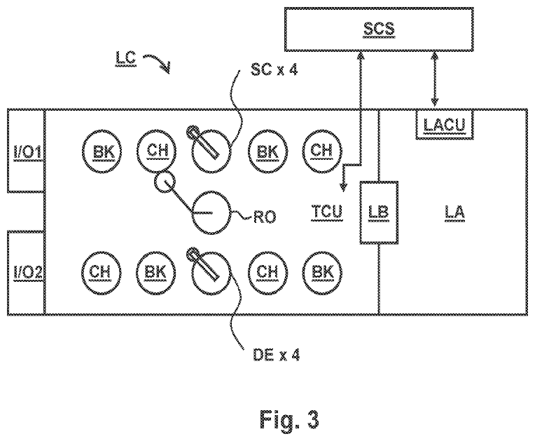

FIG. 3 illustrates a lithographic cell or cluster. the lithographic apparatus LA may form part of a lithographic cell LC, also sometimes referred to a lithocell or cluster, which also includes apparatuses to perform pre- and post-exposure processes on a substrate. Conventionally these include one or more spin coaters SC to deposit one or more resist layers, one or more developers DE to develop exposed resist, one or more chill plates CH and/or one or more bake plates BK. A substrate handler, or robot, RO picks up one or more substrates from input/output port I/O1, I/O2, moves them between the different process apparatuses and delivers them to the loading bay LB of the lithographic apparatus. These apparatuses, which are often collectively referred to as the track, are under the control of a track control unit TCU which is itself controlled by the supervisory control system SCS, which also controls the lithographic apparatus via lithography control unit LACU. Thus, the different apparatuses can be operated to maximize throughput and processing efficiency.

In order that a substrate that is exposed by the lithographic apparatus is exposed correctly and consistently, it is desirable to inspect an exposed substrate to measure or determine one or more properties such as overlay (which can be, for example, between structures in overlying layers or between structures in a same layer that have been provided separately to the layer by, for example, a double patterning process), line thickness, critical dimension (CD), focus offset, a material property, etc. Accordingly, a manufacturing facility in which lithocell LC is located also typically includes a metrology system MET which receives some or all of the substrates W that have been processed in the lithocell. The metrology system MET may be part of the lithocell LC, for example it may be part of the lithographic apparatus LA.

Metrology results may be provided directly or indirectly to the supervisory control system SCS. If an error is detected, an adjustment may be made to exposure of a subsequent substrate (especially if the inspection can be done soon and fast enough that one or more other substrates of the batch are still to be exposed) and/or to subsequent exposure of the exposed substrate. Also, an already exposed substrate may be stripped and reworked to improve yield, or discarded, thereby avoiding performing further processing on a substrate known to be faulty. In a case where only some target portions of a substrate are faulty, further exposures may be performed only on those target portions which are good.

Within a metrology system MET, a metrology apparatus is used to determine one or more properties of the substrate, and in particular, how one or more properties of different substrates vary or different layers of the same substrate vary from layer to layer. The metrology apparatus may be integrated into the lithographic apparatus LA or the lithocell LC or may be a stand-alone device. To enable rapid measurement, it is desirable that the metrology apparatus measure one or more properties in the exposed resist layer immediately after the exposure. However, the latent image in the resist has a low contrast—there is only a very small difference in refractive index between the parts of the resist which have been exposed to radiation and those which have not—and not all metrology apparatus have sufficient sensitivity to make useful measurements of the latent image. Therefore measurements may be taken after the post-exposure bake step (PEB) which is customarily the first step carried out on an exposed substrate and increases the contrast between exposed and unexposed parts of the resist. At this stage, the image in the resist may be referred to as semi-latent. It is also possible to make measurements of the developed resist image—at which point either the exposed or unexposed parts of the resist have been removed—or after a pattern transfer step such as etching. The latter possibility limits the possibilities for rework of a faulty substrate but may still provide useful information.

To enable the metrology, one or more targets can be provided on the substrate. In an embodiment, the target is specially designed and may comprise a periodic structure. In an embodiment, the target is a part of a device pattern, e.g., a periodic structure of the device pattern. In an embodiment, the device pattern is a periodic structure of a memory device (e.g., a Bipolar Transistor (BPT), a Bit Line Contact (BLC), etc. structure).

In an embodiment, the target on a substrate may comprise one or more 1-D periodic structures (e.g., gratings), which are printed such that after development, the periodic structural features are formed of solid resist lines. In an embodiment, the target may comprise one or more 2-D periodic structures (e.g., gratings), which are printed such that after development, the one or more periodic structures are formed of solid resist pillars or vias in the resist. The bars, pillars or vias may alternatively be etched into the substrate (e.g., into one or more layers on the substrate).

In an embodiment, one of the performance parameters of interest of a patterning process is overlay. In some embodiments, overlay can be measured using dark field scatterometry in which the zeroth order of diffraction (corresponding to a specular reflection) is blocked, and only higher orders processed. Examples of dark field metrology can be found in PCT patent application publication no. WO 2009/078708 and WO 2009/106279, which are hereby incorporated in their entirety by reference. Further developments of the technique have been described in U.S. patent application publications US2011-0027704, US2011-0043791 and US2012-0242970, which are hereby incorporated in their entirety by reference. Diffraction-based overlay using dark-field detection of the diffraction orders enables overlay measurements on smaller targets. These targets can be smaller than the illumination spot and may be surrounded by device product structures on a substrate. In an embodiment, multiple targets can be measured in one radiation capture. However, it will be appreciated by those skilled in the art that present disclosure is not limited to any specific type of overlay measurement mechanism or system.

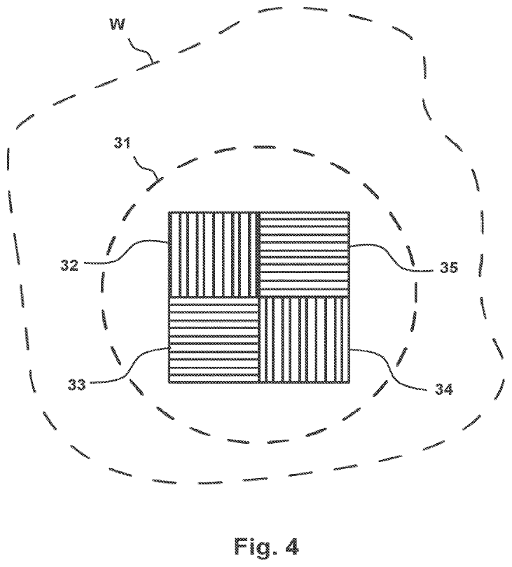

FIG. 4 depicts a form of multiple periodic structure (e.g., multiple grating) target and an outline of a measurement spot on a substrate.

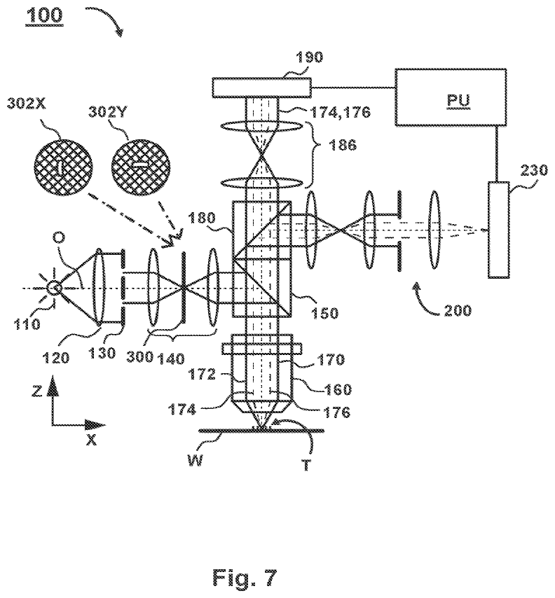

FIG. 4 depicts an example composite metrology target T formed on a substrate. The composite target comprises four periodic structures (in this case, gratings) 32, 33, 34, 35 positioned closely together. In an embodiment, the periodic structure layout may be made smaller than the measurement spot (e.g., the periodic structure layout is overfilled). Thus, in an embodiment, the periodic structures are positioned closely together enough so that they all are within a measurement spot 31 formed by the illumination beam of the metrology apparatus. In that case, the four periodic structures thus are all simultaneously illuminated and simultaneously imaged on sensors 190 and 230 (see FIG. 7). In an example dedicated to overlay measurement, periodic structures 32, 33, 34, 35 are themselves composite periodic structures (e.g., composite gratings) formed by overlying periodic structures, e.g., periodic structures are patterned in different layers of the device formed on substrate W and such that at least one periodic structure in one layer overlays at least one periodic structure in a different layer. Such a target may have outer dimensions within 20 μm×20 μm or within 16 μm×16 μm. Further, in an embodiment, all the periodic structures are used to measure overlay between a particular pair of layers. To facilitate a target being able to measure more than a single pair of layers, periodic structures 32, 33, 34, 35 may have differently biased overlay offsets in order to facilitate measurement of overlay between different layers in which the different parts of the composite periodic structures are formed. Thus, all the periodic structures for the target on the substrate would be used to measure one pair of layers and all the periodic structures for another same target on the substrate would be used to measure another pair of layers, wherein the different bias facilitates distinguishing between the layer pairs.

Returning to FIG. 4, periodic structures 32, 33, 34, 35 may also differ in their orientation, as shown, so as to diffract incoming radiation in X and Y directions. In one example, periodic structures 32 and 34 are X-direction periodic structures with biases of +d, −d, respectively. Periodic structures 33 and 35 may be Y-direction periodic structures with offsets +d and −d respectively. While four periodic structures are illustrated, another embodiment may include a larger matrix to obtain desired accuracy. For example, a 3×3 array of nine composite periodic structures may have biases −4d, −3d, −2d, −d, 0, +d, +2d, +3d, +4d. Separate images of these periodic structures can be identified in an image captured by sensor 230.

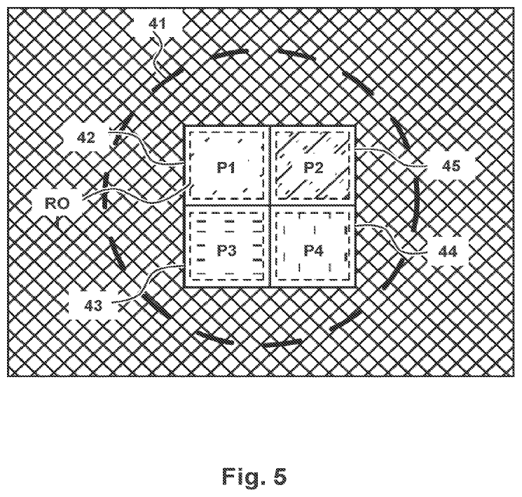

FIG. 5 schematically depicts an image of the target of FIG. 4 obtained using an apparatus of FIG. 7. FIG. 5 shows an example of an image that may be formed on and detected by the sensor 230, using the target of FIG. 4 in the apparatus of FIG. 7, using the aperture plates 130. While the sensor 190 cannot resolve the different individual periodic structures 32 to 35, the sensor 230 can do so. The dark rectangle represents the field of the image on the sensor, within which the illuminated spot 31 on the substrate is imaged into a corresponding circular area 41. Within this, rectangular areas 42-45 represent the images of the periodic structures 32 to 35. The target can be positioned in among device product features, rather than or in addition to in a scribe lane. If the periodic structures are located in device product areas, device features may also be visible in the periphery of this image field. Processor and controller PU processes these images using pattern recognition to identify the separate images 42 to 45 of periodic structures 32 to 35. In this way, the images do not have to be aligned very precisely at a specific location within the sensor frame, which greatly improves throughput of the measuring apparatus as a whole.

Once the separate images of the periodic structures have been identified, the intensities of those individual images can be measured, e.g., by averaging or summing selected pixel intensity values within the identified areas. Intensities and/or other properties of the images can be compared with one another. These results can be combined to measure different parameters of the lithographic process. Overlay performance is an example of such a parameter.

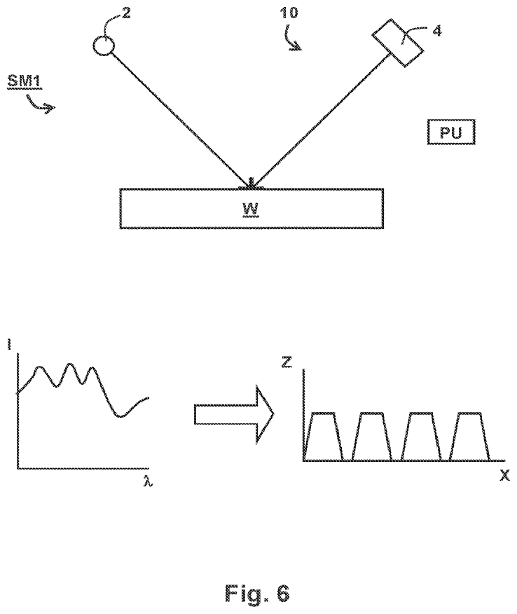

FIG. 6 depicts an example metrology apparatus and metrology technique. In an embodiment, one of the parameters of interest of a patterning process is feature width (e.g., CD). FIG. 6 depicts a highly schematic example metrology apparatus (e.g., a scatterometer) that can enable feature width determination. It comprises a broadband (white light) radiation projector 2 which projects radiation onto a substrate W. The redirected radiation is passed to a spectrometer detector 4, which measures a spectrum 10 (intensity as a function of wavelength) of the specular reflected radiation, as shown, e.g., in the graph in the lower left. From this data, the structure or profile giving rise to the detected spectrum may be reconstructed by processor PU, e.g. by Rigorous Coupled Wave Analysis and non-linear regression or by comparison with a library of simulated spectra as shown at the bottom right of FIG. 6. In general, for the reconstruction the general form of the structure is known and some variables are assumed from knowledge of the process by which the structure was made, leaving only a few variables of the structure to be determined from the measured data. Such a metrology apparatus may be configured as a normal-incidence metrology apparatus or an oblique-incidence metrology apparatus. Moreover, in addition to measurement of a parameter by reconstruction, angle resolved scatterometry is useful in the measurement of asymmetry of features in product and/or resist patterns. A particular application of asymmetry measurement is for the measurement of overlay, where the target comprises one set of periodic features superimposed on another. The concepts of asymmetry measurement in this manner are described, for example, in U.S. patent application publication US2006-066855, which is incorporated herein in its entirety.

FIG. 7 illustrates an example of a metrology apparatus 100 suitable for use in embodiments of the present disclosure. The principles of operation of this type of metrology apparatus are explained in more detail in the U.S. Patent Application Publication Nos. US 2006-033921 and US 2010-201963, which are incorporated herein in their entireties by reference. An optical axis, which has several branches throughout the apparatus, is represented by a dotted line O. In this apparatus, radiation emitted by source 110 (e.g., a xenon lamp) is directed onto substrate W via by an optical system comprising: lens system 120, aperture plate 130, lens system 140, a partially reflecting surface 150 and objective lens 160. In an embodiment these lens systems 120, 140, 160 are arranged in a double sequence of a 4F arrangement. In an embodiment, the radiation emitted by radiation source 110 is collimated using lens system 120. A different lens arrangement can be used, if desired. The angular range at which the radiation is incident on the substrate can be selected by defining a spatial intensity distribution in a plane that presents the spatial spectrum of the substrate plane. In particular, this can be done by inserting an aperture plate 130 of suitable form between lenses 120 and 140, in a plane which is a back-projected image of the objective lens pupil plane. Different intensity distributions (e.g., annular, dipole, etc.) are possible by using different apertures. The angular distribution of illumination in radial and peripheral directions, as well as properties such as wavelength, polarization and/or coherency of the radiation, can all be adjusted to obtain desired results. For example, one or more interference filters 130 can be provided between source 110 and partially reflecting surface 150 to select a wavelength of interest in the range of, say, 400-900 nm or even lower, such as 200-300 nm. The interference filter may be tunable rather than comprising a set of different filters. A grating could be used instead of an interference filter. In an embodiment, one or more polarizers 170 can be provided between source 110 and partially reflecting surface 150 to select a polarization of interest. The polarizer may be tunable rather than comprising a set of different polarizers.

As shown in FIG. 7, the target T is placed with substrate W normal to the optical axis O of objective lens 160. Thus, radiation from source 110 is reflected by partially reflecting surface 150 and focused into an illumination spot S on target Ton substrate W via objective lens 160. In an embodiment, objective lens 160 has a high numerical aperture (NA), desirably at least 0.9 or at least 0.95. An immersion metrology apparatus (using a relatively high refractive index fluid such as water) may even have a numerical aperture over 1.

Rays of illumination 170, 172 focused to the illumination spot from angles off the axis O gives rise to diffracted rays 174, 176. It should be remembered that these rays are just one of many parallel rays covering an area of the substrate including target T. Each element within the illumination spot is within the field of view of the metrology apparatus. Since the aperture in plate 130 has a finite width (necessary to admit a useful quantity of radiation), the incident rays 170, 172 will in fact occupy a range of angles, and the diffracted rays 174, 176 will be spread out somewhat. According to the point spread function of a small target, each diffraction order will be further spread over a range of angles, not a single ideal ray as shown.

At least the 0^{th} order diffracted by the target on substrate W is collected by objective lens 160 and directed back through partially reflecting surface 150. An optical element 180 provides at least part of the diffracted beams to optical system 182 which forms a diffraction spectrum (pupil plane image) of the target Ton sensor 190 (e.g. a CCD or CMOS sensor) using the zeroth and/or first order diffractive beams. In an embodiment, an aperture 186 is provided to filter out certain diffraction orders so that a particular diffraction order is provided to the sensor 190. In an embodiment, the aperture 186 allows substantially or primarily only zeroth order radiation to reach the sensor 190. In an embodiment, the sensor 190 may be a two-dimensional detector so that a two-dimensional angular scatter spectrum of a substrate target T can be measured. The sensor 190 may be, for example, an array of CCD or CMOS sensors, and may use an integration time of, for example, 40 milliseconds per frame. The sensor 190 may be used to measure the intensity of redirected radiation at a single wavelength (or narrow wavelength range), the intensity separately at multiple wavelengths or integrated over a wavelength range. Furthermore, the sensor may be used to separately measure the intensity of radiation with transverse magnetic- and/or transverse electric-polarization and/or the phase difference between transverse magnetic- and transverse electric-polarized radiation.

Optionally, optical element 180 provides at least part of the diffracted beams to measurement branch 200 to form an image of the target on the substrate Won a sensor 230 (e.g. a CCD or CMOS sensor). The measurement branch 200 can be used for various auxiliary functions such as focusing the metrology apparatus (e.g., enabling the substrate W to be in focus with the objective 160), and/or for dark field imaging of the type mentioned in the introduction.

In order to provide a customized field of view for different sizes and shapes of grating, an adjustable field stop 300 is provided within the lens system 140 on the path from source 110 to the objective lens 160. The field stop 300 contains an aperture 302 and is located in a plane conjugate with the plane of the target T, so that the illumination spot becomes an image of the aperture 302. The image may be scaled according to a magnification factor, or the aperture and illumination spot may be in 1:1 size relation. In order to make the illumination adaptable to different types of measurement, the aperture plate 300 may comprise a number of aperture patterns formed around a disc, which rotates to bring a desired pattern into place. Alternatively or in addition, a set of plates 300 could be provided and swapped, to achieve the same effect. Additionally or alternatively, a programmable aperture device such as a deformable mirror array or transmissive spatial light modulator can be used also.

Typically, a target will be aligned with its periodic structure features running either parallel to the Y axis or parallel to the X axis. With regard to its diffractive behavior, a periodic structure with features extending in a direction parallel to the Y axis has periodicity in the X direction, while the periodic structure with features extending in a direction parallel to the X axis has periodicity in the Y direction. In order to measure the performance in both directions, both types of features are generally provided. While for simplicity there will be reference to lines and spaces, the periodic structure need not be formed of lines and space. Moreover, each line and/or space between lines may be a structure formed of smaller sub-structures. Further, the periodic structure may be formed with periodicity in two dimensions at once, for example where the periodic structure comprises posts and/or via holes.

In order to monitor the lithographic process, it is necessary to measure parameters of the patterned substrate, for example the overlay error between successive layers formed in or on it. There are various techniques for making measurements of the microscopic structures formed in lithographic processes, including the use of scanning electron microscopes and various specialized tools. One form of specialized inspection tool is a scatterometer in which a beam of radiation is directed onto a target on the surface of the substrate and properties of the scattered or reflected beam are measured. By comparing the properties of the beam before and after it has been reflected or scattered by the substrate, the properties of the substrate can be determined. This can be done, for example, by comparing the reflected beam with data stored in a library of known measurements associated with known substrate properties. Two main types of scatterometer are known. Spectroscopic scatterometers direct a broadband radiation beam onto the substrate and measure the spectrum (intensity as a function of wavelength) of the radiation scattered into a particular narrow angular range. Angularly resolved scatterometers use a monochromatic radiation beam and measure the intensity of the scattered radiation as a function of angle.

Devices are built up layer by layer and overlay is a measure of a lithographic apparatus' ability to print these layers accurately on top of each other. Successive layers or multiple processes on the same layer must be accurately aligned to the previous layer, otherwise electrical contact between structures will be poor and the resulting devices will not perform to specification. Overlay is a measure of the accuracy of this alignment. Good overlay improves device yield and enables smaller product patterns to be printed. The overlay error between successive layers formed in or on the patterned substrate is controlled by various parts of the exposure apparatus (of the lithographic apparatus). It is mostly the alignment system of the lithographic apparatus that is responsible for the alignment of the radiation onto the correct portions of the substrate.

Overlay may be measured using an “image-based” (box-in-box) technique or Diffraction-Based Overlay (DBO) metrology. DBO is an emerging metrology technique used because its TMU (Total Measurement Uncertainty) is typically better compared to “image-based” techniques. In the “image-based” case, overlay may be derived from a measurement of the position of a resist marker pattern relative to a marker pattern in an earlier formed product layer. In the DBO case, overlay is indirectly measured, for example by detecting a shape of an interference pattern from diffracted beams of two similar grating structures such as a top layer (e.g., resist layer) grating stacked over a bottom layer (e.g., product layer) grating.

A semiconductor chip manufacturing involves one or more processes performed on a substrate to form a desired pattern on the substrate. The one or more processes (e.g., lithographic, resist development, etching, chemical deposition, etc.) may induce overlay errors between two layers of the substrate. The overlay of the substrate may be represented as an overlay fingerprint that includes overlay induced by the one or more processes. In some embodiments, an overlay fingerprint induced by a process may be different from overlay fingerprint induced by another process. The overlay fingerprint may be for an intra-field or an intra-die of the substrate. For example, intra-field refers one or more instances of patterning using the same patterning device M at a different location on the substrate W. Intra-die refers to overlay fingerprint associated with different dies of the substrate.

In an embodiment, intra-field and intra-die process overlay fingerprint exists because of a non-uniformity in a chip layout (e.g., a pattern density non-uniformity). Such non-uniformity in pattern density often interacts with a specific process (e.g. deposition causing thin film stress and etching causing etch loading effect) and results in a process overlay fingerprint. Such a process overlay fingerprint, if accurately measured or predicted, can be corrected using an overlay optimizer (e.g., ASML's OVO2/3/4) or optical proximity correction (OPC) products.

Currently, overlay fingerprints are measured using optical CD-type of measurements via a metrology tool such as in device metrology (IDM) (e.g., see FIG. 7). As an example, the in device metrology tool includes a scatterometer which measures in pupil (e.g., using visible wavelengths) and is suitable for measuring in-device targets of 5×5 μm² or smaller (the illumination spot being 2 μm or similar). However, for complicated stack of layers formed on the substrate including non-periodic logic (e.g., system on chip (SoC)) circuit patterns, optical CD measurements are not possible. For such patterns, a scattering electron microscope (SEM) may be employed. However, even if a few local measurements (e.g., with CD-SEM) are made on substrate features, it is difficult to extrapolate the sparsely sampled result to the full field or the full die because of unknown physical mechanism that generates the overlay fingerprint.

The present disclosure describes a mechanism for designing a structure that enables measurement of a process parameter (e.g., overlay) and enables extraction of process induced fingerprints in the process parameter (e.g., overlay fingerprints). In an embodiment, a designed structure is also referred as a metrology mark structure or a mark structure. In an embodiment, a metrology mark structure may be formed on the substrate extending along an area sufficiently large compared to the length scales of a process effects (e.g., etching loading or film stress) of interest. For example, approximately 10-200 μm in case of etch/film stress effects on (local) overlay. The metrology mark structure may be formed on a layer (e.g., a top layer) of the substrate, and overlay measurements between features on the layer (e.g., a top layer) and features on a bottom layer can be obtained.

In an embodiment, designing of the metrology mark structure involves density modulation of features of the metrology structure. In an embodiment, top layer features may be aligned to bottom layer features and density modulation of top layer features may be performed. Such density modulation enables extraction or separation of process-specific overlay fingerprints using a function characterizing physical effects of a process.

In an embodiment, a density modulation can be achieved by changing size, shape, count, etc. of the features. In an embodiment, density modulation is achieved based on a pattern density map that is derived based on a potential function for which a gradient correspond to an overlay fingerprint. The potential function may be any suitable differentiable function (e.g., parabolic, trigonometric, etc.). In an embodiment, the potential function can be expressed as a convolution of the density function D that characterizes density of features in a pattern and a kernel K that characterizes a semiconductor manufacturing process. For example, a potential function P equal to convolution of density function (D) with kernel (K), which can be symbolically written as P=D(K). The aforementioned relationship can be rewritten (e.g., applying inverse) to compute the density function D. In an embodiment, inverse Fourier transform may be applied to compute inverse of functions to determine density function D.

In an embodiment, the density function D may converted to a metrology mark structure including a pattern compliant with a pattern density requirement (e.g., including mask rule check), which may be applied to a reticle. In an embodiment, overlay data across the metrology mark structure may be measured using a metrology tool (e.g., SEM). In an embodiment, the overlay data may represented as a vector field indicating a magnitude and a direction of overlay. In an embodiment, back propagating the overlay data allows inference of a kernel(s) characterizing the process. For example, the kernel may reveal what process steps contribute to which extend to the overlay fingerprint.

In an embodiment, the metrology mark structure may be used for intra-field or intra-die overlay monitoring. Overlay fingerprints measured at the metrology mark structure of the substrate may have various applications including, but not limited to, overlay control and process control. For example, the designed structure can directly measure a stress level on the substrate, and the measured stress level can be further used to optimize customer thin film process. In an embodiment, the metrology mark structure can be used to separate different physical modes and length scales that induces an overlay fingerprint. This separation of overlay fingerprints may be used to identify root causes of an overlay fingerprint (e.g., overlay fingerprint caused due to etching loading effect or thin film stress).

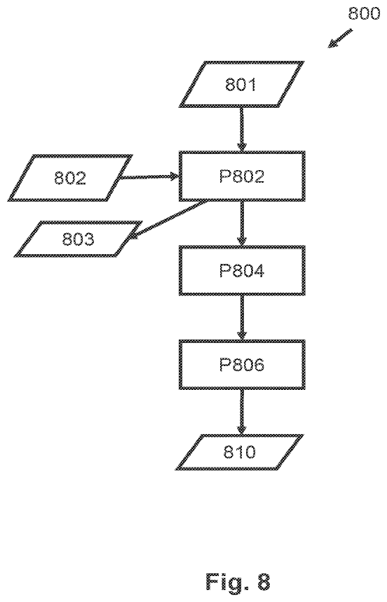

FIG. 8 is a flow chart of a method 800 for designing a metrology mark structure for measuring process characteristics of one or more semiconductor manufacturing processes, according to an embodiment. The metrology mark structure is determined by density modulation of features based on a pattern distribution. In an embodiment, features of the metrology mark structure may have a non-periodic structure and formed on a first layer, and features on a second layer have period structure. Upon forming the metrology mark structure and measuring overlay at the metrology mark structure on the substrate, a process kernel may be used to separate process induced overlay fingerprints form the measured overlay. The method 800 is further discussed in detail with respect to exemplary processes P802, P804, and P806 below.

Process P802 includes obtaining a first function 801 to characterize an overlay fingerprint induced by a semiconductor manufacturing process performed on a substrate. In an embodiment, an overlay fingerprint is a representation of an overlay between relative position of a pattern on a first layer and another pattern on a second layer of the substrate. The first function may be a user-specified function representing a desired overlay fingerprint characterization or property.

In an embodiment, the first function 801 may be obtained by determining a differentiable function, or so-called potential function, whose gradient is equivalent to the overlay fingerprint induced by the semiconductor manufacturing process. However, it will be appreciated that the present disclosure is not limited to any specific characterization or property of an overlay fingerprint that can be represented by the first function. In an embodiment, the first function 801 is at least one of: a parabolic function of one or more dimensions of the substrate; a trigonometric function of one or more dimensions of the substrate; or an inverse function of one or more dimensions of the substrate. In an embodiment, the first function 801 may be expressed in terms of coordinates used to describe a space on a substrate. For example, the first function 801 may be expressed as a function of x, y or polar coordinates.

In an embodiment, a first function 801 may be represented as p(x, y) and overlay may be expressed as a displacement vector (uₓ,u_{y}). The relationship between the first function 801 and overlay may be expressed as overlay being a gradient of the first function 801. For example, the relationship is symbolically represented as (uₓ,u_{y})=∇ₚ(x, y).

Process P804 includes deriving, based on the first function 801, a pattern distribution 803, which is indicative of a number of features within a portion of the substrate. For example, the pattern distribution may be indicative of a density of features within a portion of the substrates. Density of features may be computed by an area of the features divided by an area of the portion of the substrate.

In an embodiment, the pattern distribution 803 is derived by deconvolving the first function 801 using a second function 802, wherein the second function 802 characterizes a physical effect of the semiconductor manufacturing process on a layer of the substrate.

In an embodiment, the second function 802 is separable upon convolving with the pattern distribution 803. In an embodiment, the second function 802 may comprise a kernel function which is a function of a dimension (e.g., length) of the substrate allowing the second function 802 to capture changes in the overlay fingerprint at different lengths on the substrate. In an embodiment, the kernel function is a Gaussian kernel having a length as a parameter that captures a physical effect of the process on the overlay. For example, the physical effect of a process (e.g., etching) at a first length appears as a first contribution in the overlay, at a second length appears as a second contribution in the overlay, etc. In an embodiment, the second function 802 comprises at least one of: a diffusion kernel characterizing a redistribution of surface charges during an etching process that contributes to the overlay fingerprint; or a stress kernel characterizing a stress released during an etching process that contributes to the overlay fingerprint.

In an embodiment, a relationship between a pattern density 803 and overlay (e.g., represented as displacement (uₓ, u_{y})) may be expressed as:

OVL=∇[D(x,y)⊗K(x,y)]

In the above equation, D (x, y) denotes pattern distribution as a function of Cartesian coordinate; K(x, y) denotes second function (e.g., process kernel function); ⊗ is convolution operator;

$$∇ = ( \frac{d}{dx} , \frac{d}{dy} )$$

is the gradient operator. In an embodiment, the above model form assumes process overlay fingerprint is additive on pattern density, and assumes no curl component on the overlay field.

One examples of the second function K(x, y) may be an inverse power kernel function that characterizes stress induced overlay. The inverse power kernel function may include a first parameter corresponding to a thickness of a film on the substrate, and a second parameter indicative of a length on the substrate. As such, by varying the first parameter the inverse power kernel function can be configured to determine a stress induced overlay for different thicknesses, and by varying the second parameter the kernel function can be configured to determine a stress induced overlay at different lengths.

Another example of the second function K(x, y) may be Gaussian kernel for diffusion related processes, e.g. etchant concentration that characterizes diffusion induced overlay. The Gaussian kernel function may include a length parameter indicative of a length on the substrate. As such, by varying the length parameter the Gaussian kernel function can be configured to determine a diffusion induced overlay at different lengths.

An overlay fingerprint of the substrate as measured can be attributed to a combination of multiple processes that the substrate has been subject to. It is useful to separate each process fingerprint contribution to determine root causes of the overlay fingerprint. The metrology mark structures described herein engineers a characteristic overlay fingerprint that can be calculated by one or more kernel functions and test a measured deviation from the engineered overlay fingerprint. In an embodiment, by multilinear regression the process induced overlay fingerprints can be separated out.

In an embodiment, the deriving of the pattern distribution 803 includes applying a Fourier transform to the first function 801 and the second function 802 to obtain a transformed first function and a transformed second function; dividing the transformed first function by the transformed second function; and subsequently applying an inverse Fourier transform to determine the pattern distribution 803 of a metrology mark structure.

In an embodiment, the pattern distribution 803 may be determined as discussed above and symbolically explained as follows. For example, the pattern density distribution 803 may be determined by deconvolving the first function using the second function to get the pattern distribution function. For example, symbolically, D (x, y)=p(x, y)O/K(x, y), where O/ represents a deconvolution operator. In an embodiment, the deconvolution may be computed by fast Fourier transformation. For example, the above equation may be formulated as follows:

$$D ( x , y ) = ifft 2 [ \frac{fft 2 ( p ( x , y ) )}{ξ + fft 2 ( K ( x , y ) )} ]$$

In the above equation, ξ is a small number added to avoid singularity, ƒƒt2 represents the fast Fourier transformation function, and iƒƒt2 represents the inverse fast Fourier transformation function.

In an embodiment, the pattern distribution function D (x, y) may be binarized by applying a binary threshold to values of D (x, y) corresponding at each (x, y) coordinates. As an example, the binarization may be achieved as follows: for D(x, y)>threshold, D(x, y) is assigned value 1; and for D (x, y)<=threshold, D (x, y) is assigned value 0. In an embodiment, the purpose of binarization of the pattern distribution may be to enlarge the magnitude of an overlay fingerprint.

Process P806 includes determining, based on the pattern distribution 803, physical characteristics of the features of a metrology mark structure 810 for disposing the substrate. For example, the pattern distribution obtained as a function represented as D (x, y) can be further used to determine features of a metrology mark structure 810. In an embodiment, the determining of the features for the metrology mark structure involves density modulation by changing size, shape, etc. of the features. For example, by density modulation one or more patterns may be designed as squares on a uniform mesh grid, with its local pattern density modulated by the side length of the squares. The density modulated patterns may be represented (or formed) on a top layer of the substrate. In an embodiment, bottom layer features can be designed as smaller squares, with edges contained by the top layer squares. This would enable local overlay measurement by SEM after an etching process.

In an embodiment, physical characteristics of the features may be determined by varying polygon shapes of the metrology mark structure 810 based on the pattern distribution 803. For example, a first set of polygon shapes (e.g., squares) comprises polygon shapes distinct from polygon shapes of a second set of polygon shapes (e.g., circular). In an embodiment, the physical characteristics may be determined by varying positioning of the features relative to each other.

In an embodiment, the physical characteristics of the features may be determined based on a set of geometric constraints and the pattern distribution 803 to generate the set of polygon shapes of the metrology mark structure 810. In an embodiment, based on distance constraints between the features and the pattern distribution 803, a positioning between polygon shapes of the first set of polygon shapes or the second set of polygon shapes may be determined. In an embodiment, the set of geometric constraints includes a set of threshold values related to shape, size, and/or relative positioning of polygon shapes with respect to each other.

In an embodiment, determining the physical characteristics of the features is an iterative process, each iteration involves distributing, based on the pattern distribution 803, an initial set of polygon shapes within a portion of the metrology mark structure 810; determining whether the set of geometric constraints associated with the initial set of polygon shapes are satisfied; responsive to one or more geometric constraints not being satisfied, modifying a shape of one or more polygon shapes of the initial set of polygon shapes causing the one or more geometric constraints to be satisfied; and including the modified polygon shapes in a set of the set of polygon shapes.

In an embodiment, the metrology mark structure 810 may be formed on the first layer. In an embodiment, features of the metrology mark structure 810 on the first layer have a non-periodic structure, and features on the second layer have period structure.

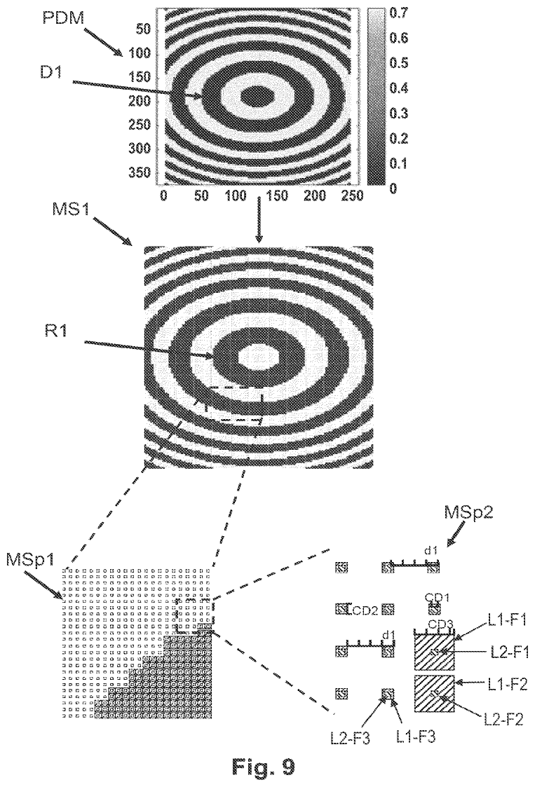

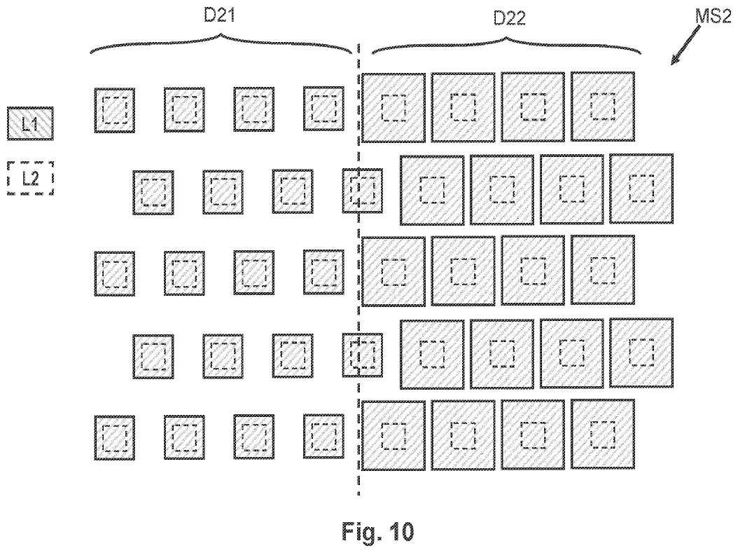

FIGS. 9-12 illustrate examples of metrology mark structures generated using a pattern distribution or a pattern density map as a guide to determine polygon shapes of features of the metrology structures. FIG. 9 illustrates an example pattern density map PDM having varying density across a portion of the substrate. FIGS. 10, 11, 12 illustrate different metrology mark structures that can be generated using varying density of the pattern density map PDM as guide. The features in FIGS. 9-12 are filled with grey color or hatching to visually distinguish between different layers. In an embodiment, the features may be represented as polygons or functions characterizing, each polygon characterizing an outline of the feature.

Referring to FIG. 9, the pattern density map PMD may be obtained using a first function associated with an overlay fingerprint and a kernel function associated with a process effect, as discussed herein. As an example, the pattern density map PDM is represented as image, wherein pixel intensities are indicative of an amount of feature. For example, a higher pixel intensity portions within the image indicate that such portions should have a higher density of features than other portions. Using the pattern density map PDM as a guide, a metrology mark structure MS1 is designed such that density of features within the metrology mark structure MS1 correspond to density of the pattern density map PDM. For example, a dark ring R1 of MS1 correspond to higher density ring D1. The features of the metrology mark structure MS1 are better visible in enlarged portions MSp1 and MSp2.

An enlarged portion MSp1 of the metrology mark structure MS1 shows example features within the metrology mark structure MS1. As shown within the portion MSp1, a lower right corner region has a higher density compared to other regions of the portion MSp1. In an example, a high density region may be achieved by populating the lower right corner region with features having CD greater than CD of features in other regions of the portion MSp1. In the present example, the metrology mark structure MS1 includes square shaped features arranged as an array, where some squares are larger than others. However, any other suitable shapes can also be used without departing from the scope of the present disclosure. The square shaped features of the metrology mark structure MS1 may be formed on a layer L1. The portion MSp1 also shows smaller squares formed on another layer (e.g., a layer L2) below a layer (e.g., layer L1) on which the metrology mark structure MS1. In an example, overlay may be measured between edges of the features between the two layers.

A further enlarged portion MSp2 of portion MSp1 shows more details associated with the features. The portion MSp2 shows features L1-F1, L1-F2, and L1-F3 included on layer L1 (indicated by hatching). These features of the metrology structure may be disposed on top of features L2-F1, L2-F2, and L2-F3 included on a layer L2, where each feature has CD value of CD1 (e.g., 0.05 μm). In an embodiment, the features may be square shaped having different CDs such as CD2 and CD3. For example, small features like L1-F3 have CD2 (e.g., 0.08 μm) and large features like L1-F1 and L1-F2 have CD3 (e.g., 0.3 μm). Additionally, in an embodiment, the density may be varied by changing a distance between the features of MS1. In the present example, the distance between small features like L1-F3 may be dl (e.g., 0.4 μm).

FIG. 10 illustrates another metrology mark structure MS2 (on layer L1) generated using the pattern density map (e.g., map PDM in FIG. 9). The metrology mark structure MS2 comprises a low density region D1 characterized by a small sized features and a high density region D2 characterized by a large sized features. As shown, some features on layer L1 have different sizes and are non-uniformly spaced. In an embodiment, the metrology mark structure MS2 may be disposed above another layer L2, which has an array of small features (dotted) that are equidistant from each other. When such metrology mark structure MS2 may be printed on a substrate and corresponding overlay measurements are obtained, particular process induced overlay fingerprints (e.g., stress related, diffusion related, etc.) may be extracted using the kernels used to design the structure MS2.

FIG. 10 illustrates another metrology mark structure MS2 (on a layer L1 of a substrate) generated using the pattern density map (e.g., map PDM in FIG. 9). The metrology mark structure MS2 comprises a low density region D21 characterized by a small sized features and a high density region D22 characterized by a large sized features. As shown, some features on layer L1 have different sizes and are non-uniformly spaced. In an embodiment, the metrology mark structure MS2 may be disposed above another layer L2, which has an array of small features (dotted) that are equidistant from each other.

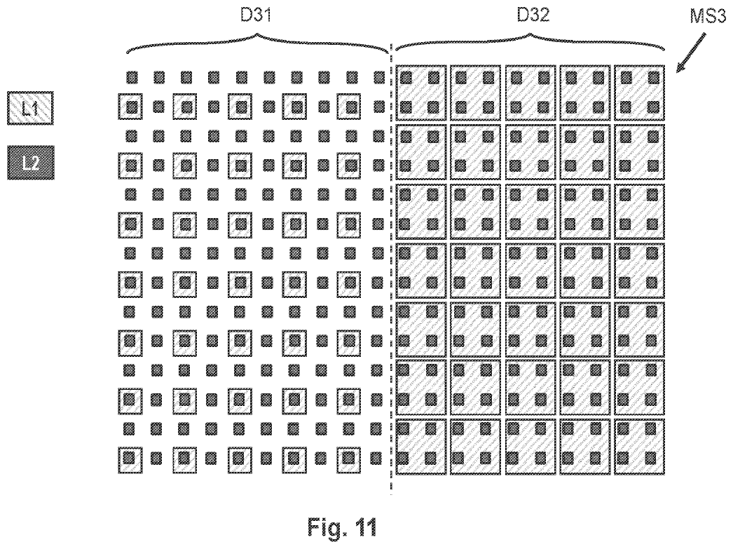

FIG. 11 illustrates another metrology mark structure MS3 (on a layer L1 of a substrate) generated using the pattern density map (e.g., map PDM in FIG. 9). The metrology mark structure MS3 comprises a low density region D31 characterized by a small sized features and a high density region D32 characterized by a large sized features. Compared to features in density regions D21 and D22 (of FIG. 10) and features in density regions D31 and D32 (of FIG. 11), shapes, sizes, and distance between features may be different although the density (e.g., D21 and D31, and D22 and D32) may be approximately same. In FIG. 11, features have same shapes such as square, but different sizes. These features shapes and sizes may be different from shapes of features in MS1 or MS2. As shown in FIG. 11, some features on the layer L1 have different sizes and are non-uniformly spaced. In an embodiment, the metrology mark structure MS3 may be disposed above another layer L2, which has an array of small features (dotted) that are equidistant from each other.

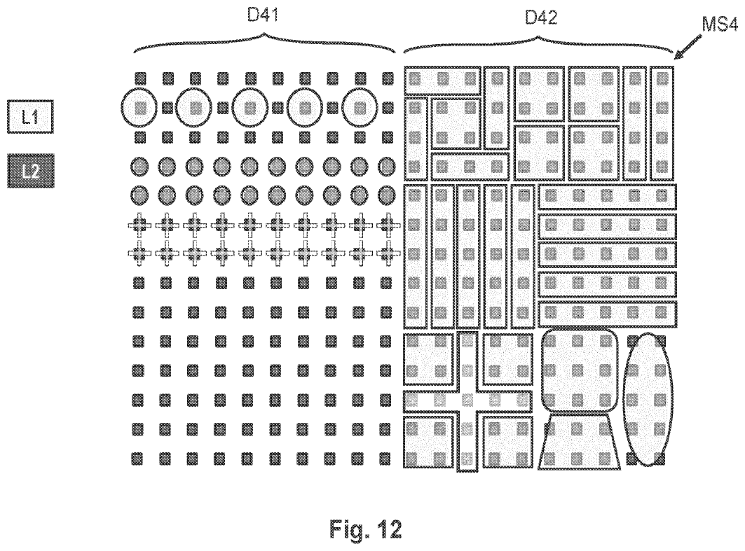

FIG. 12 illustrates another metrology mark structure MS4 (on a layer L1 of a substrate) generated using the pattern density map (e.g., map PDM in FIG. 9). The metrology mark structure MS4 comprises a low density region D41 characterized by a small sized features and a high density region D42 characterized by a large sized features. Compared to features in density regions D21 and D22 (of FIG. 10) and features in density regions D41 and D42 (of FIG. 12), shapes, sizes, and distance between features may be different although the density (e.g., D21 and D41, and D22 and D42) may be approximately same. In FIG. 12, features can of different shapes such as rectangular, square, plus, circular, etc., which are different from shapes of features in MS2 or MS3. As shown in FIG. 12, some features on the layer L1 have different sizes and are non-uniformly spaced. In an embodiment, the metrology mark structure MS3 may be disposed above another layer L2, which has an array of small features (dotted) that are equidistant from each other.

When such metrology mark structure MS1, MS2, MS3, or MS4 are printed on a substrate and corresponding overlay measurements are obtained, particular process-induced overlay fingerprints may be extracted using the kernels used to design the metrology mark structures.

In an embodiment, the metrology mark structure may be formed on the substrate on a top layer and overlay measurements may be obtained. In an embodiment, the method 800 may further include obtaining (e.g., via a metrology tool) measurement of an overlay of a patterned substrate at the metrology mark structure 810; predicting an overlay fingerprint using a pattern density function associated with the metrology mark structure 810 and a set of second functions 802s characterizing physical effects of a set of processes performed on the patterned substrate; and determining, based on the measured overlay and the predicted overlay fingerprint, an overlay fingerprint contribution of each of the set of processes performed on the patterned substrate. In an embodiment, the overlay fingerprint contribution may be determined by fitting the predicted overlay fingerprint to the measured overlay. For example, a multilinear regression may be performed by tuning parameters associated with the set of second functions 802s.

For example, after the substrate is processed, local overlay (uₓ,u_{y}) may be measured at the metrology mark structure area, the measured overlay comprising process induced fingerprints. In an embodiment, local overlay can be determined as measured position of the features minus layout (e.g., GDS or OAS file) position. In an embodiment, an overlay fingerprint library may be generated from a designed pattern distribution D(x, y) and different kernels Kᵢ (where i represents a first process, a second process, a third process, and so on), expressed in equation below:

(uₓᵢ,u_{yi})=∇[D(x,y)⊗Kᵢ]

In an embodiment, fingerprint mapping may be performed using a fitting technique such as a multilinear regression that models a relationship between the measured and one or more computed fingerprints. The fingerprint mapping may be expressed in equation below:

(uₓ,u_{y})=Σᵢ∇[D(x,y)└Kᵢ]=∇[D(x,y)⊗ΣᵢCᵢKᵢ]

For example, Cᵢ may be the fitting coefficient applied to a kernel function. In an embodiment, after fitting, an overlay fingerprint contribution of a process may be obtained by convolving a corresponding fitted kernel K with density distribution.

In an embodiment, the method 800 may further include adjusting, based on an overlay fingerprint contribution of a process obtained after the multilinear regression, process parameters of the set of processes to reduce the overlay fingerprint contribution associated with the process. In an embodiment, the method 800 may further include separating a diffusion fingerprint and a stress fingerprint from the measured overlay fingerprint of the metrology mark structure 810 by measuring an overlay response of the second function 802 on the metrology mark structure 810.

In an embodiment, a pattern distribution D may be derived using the first function p(x, y) may be a parabolic function and the second function may be a Gaussian kernel K having a variable length that enables different length based process induced fingerprints. For example, at a length of 30 (unit same as x and y units). Using the pattern distribution D, a process fingerprint may be very different at different Gaussian length. For example, at a length below 30, a convolved pattern distribution D may have multiple stripes; the gradient representing overlay (e.g., arrows having size and direction) has alternating directions. At a length equal or above 30, the convolved pattern distribution D may have a gradient (e.g., representing overlay) with arrows pointing towards the center of the substrate.

As mentioned herein, separability of different process fingerprints and sensitivity of the overlay fingerprints to length scale provides several advantages. Therefore it is advantageous to engineer a pattern distribution that is sensitive to the length scale change, which is analogous to a bandpass filter. Such an optimization can be done with numerical methods, by defining an objective function and minimize a cost function by various optimization methods.

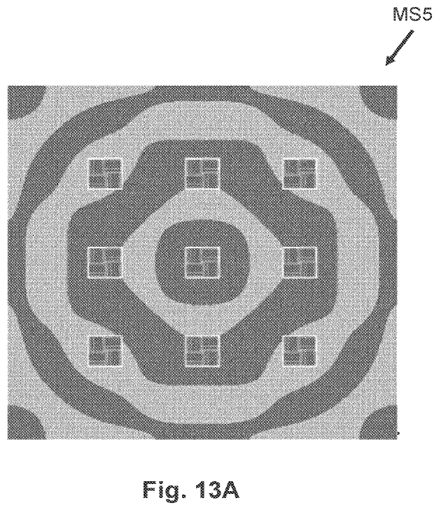

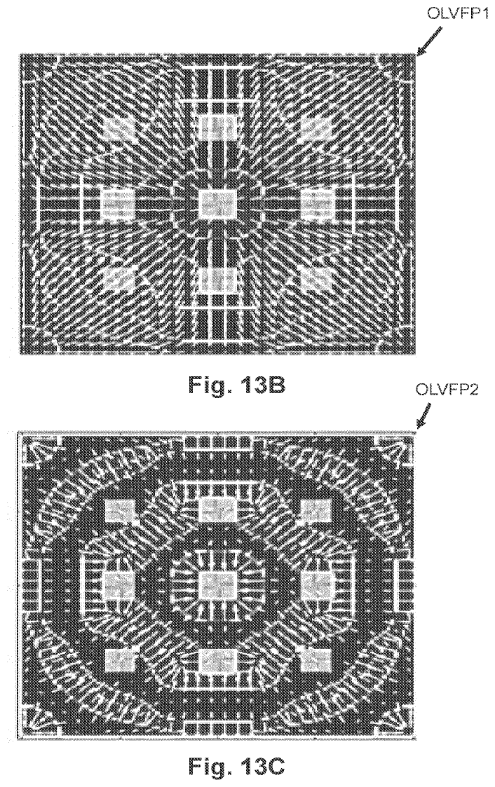

FIGS. 13A-13B illustrate an example of separating process fingerprints for a metrology mark structured designed as discussed herein. In designing the metrology mark structure, as discussed above, a first function selected may be a conical function, a kernel selected may be Gaussian kernel with a length parameter set at 40 units. In an embodiment, the metrology mark structure may be embedded with 9 μm diffraction based overlay (DBO) marks (e.g., having periodic structure) to make further use of the area. FIG. 13A illustrates an exemplary metrology mark structure configured to separate two different process induced overlay fingerprints. For example, a Gaussian kernel and inverse power function may be used in designing the metrology mark structure. As such, diffusion induced fingerprint may be separated from stress induced fingerprint using the Gaussian kernel and the inverse power function, respectively.

FIG. 13B illustrates an overlay fingerprint OVLFP1 separated using the Gaussian kernel. The overlay fingerprint OVLFP1 is represented by arrows pointing away from the center of the metrology mark structure. FIG. 13C illustrates an overlay fingerprint OVLFP2 separated using the inverse power kernel. The overlay fingerprint OVLFP2 is represented by arrows having alternating directions. Thus, overlay fingerprints OVLFP1 and OVLFP2 are very different from each other. In other words, Gaussian kernel and inverse power function may be used to predict respective process induced overlay fingerprints.

In an embodiment, the method 800 may further include extrapolating, using the set of second functions 802s, the measured overlay to an entire field of the substrate. In an embodiment, the method 800 may further include calibrating one or more process models using the extrapolated overlay of the entire field of the substrate, and determining, based on the calibrated process models, parameter values of a process for controlling the overlay induced by the process.

In an embodiment, another method (similar to method 800) may be implemented using following processes. For example, the method includes receiving a first function that characterizes an overlay fingerprint induced by semiconductor manufacturing processes performed on a substrate, the overlay fingerprint being a representation of an overlay between features on a first layer relative to features on a second layer of the substrate; receiving a second function that characterizes a physical effect of a process of the semiconductor manufacturing processes on a layer of the substrate; determining, by applying a deconvolving operation between the first function and the second function, a pattern density map for the first layer, the pattern density map indicative of a density of features within a portion of the first layer; and generating, based on the pattern density map, shapes and/or positioning of the features of the metrology mark structure.

As mentioned above, the features of the metrology mark structure may be non-uniformly distributed on the first layer causing a density of features in one portion of the metrology structure to be greater than a density of features in another portion of the metrology structure, and the features on the second layer are uniformly distributed on the second layer, the second layer formed below the first layer, wherein uniformly distributed features have a uniform spacing between the features on the second layer.

In an embodiment, a non-transitory computer-readable medium may be configured to implements the steps of methods described herein to generate the metrology mark structure, determine a process fingerprint. For example, the non-transitory computer-readable medium for generating a metrology mark structure on a chip for measuring overlay characteristics induced by semiconductor manufacturing processes performed on the chip by determining features for the metrology mark structure based on a pattern density map, the medium comprising instructions stored therein that, when executed by one or more processors, cause operations comprising process of the methods described herein.

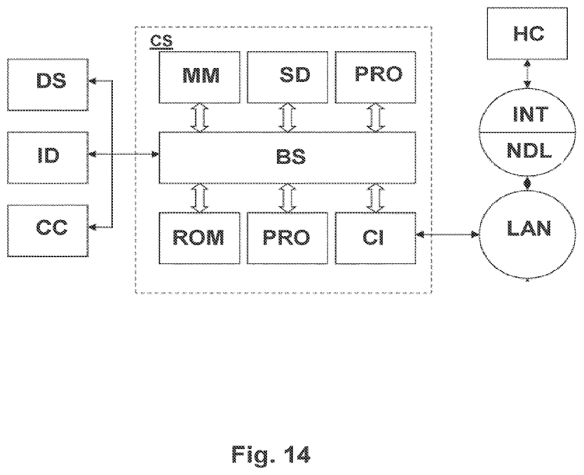

In an embodiment, a computer program product comprising a non-transitory computer readable medium having instructions recorded thereon, the instructions when executed by a computer (e.g., see FIG. 14) implementing any of the processes of the methods discussed herein.

FIG. 14 is a block diagram of an example computer system CS, according to an embodiment. The computer system CS may be used for determining overlay and controlling a process of the patterning process (e.g., in FIGS. 2 and 3), determining overlay fingerprints associated with a process or other processes of method discussed herein. Computer system CS includes a bus BS or other communication mechanism for communicating information, and a processor PRO (or multiple processor) coupled with bus BS for processing information. Computer system CS also includes a main memory MM, such as a random access memory (RAM) or other dynamic storage device, coupled to bus BS for storing information and instructions to be executed by processor PRO. Main memory MM also may be used for storing temporary variables or other intermediate information during execution of instructions to be executed by processor PRO. Computer system CS further includes a read only memory (ROM) ROM or other static storage device coupled to bus BS for storing static information and instructions for processor PRO. A storage device SD, such as a magnetic disk or optical disk, is provided and coupled to bus BS for storing information and instructions.

Computer system CS may be coupled via bus BS to a display DS, such as a cathode ray tube (CRT) or flat panel or touch panel display for displaying information to a computer user. An input device ID, including alphanumeric and other keys, is coupled to bus BS for communicating information and command selections to processor PRO. Another type of user input device is cursor control CC, such as a mouse, a trackball, or cursor direction keys for communicating direction information and command selections to processor PRO and for controlling cursor movement on display DS. This input device typically has two degrees of freedom in two axes, a first axis (e.g., x) and a second axis (e.g., y), that allows the device to specify positions in a plane. A touch panel (screen) display may also be used as an input device.

According to one embodiment, portions of one or more methods described herein may be performed by computer system CS in response to processor PRO executing one or more sequences of one or more instructions contained in main memory MM. Such instructions may be read into main memory MM from another computer-readable medium, such as storage device SD. Execution of the sequences of instructions contained in main memory MM causes processor PRO to perform the process steps described herein. One or more processors in a multi-processing arrangement may also be employed to execute the sequences of instructions contained in main memory MM. In an alternative embodiment, hard-wired circuitry may be used in place of or in combination with software instructions. Thus, the description herein is not limited to any specific combination of hardware circuitry and software.

The term “computer-readable medium” as used herein refers to any medium that participates in providing instructions to processor PRO for execution. Such a medium may take many forms, including but not limited to, non-volatile media, volatile media, and transmission media. Non-volatile media include, for example, optical or magnetic disks, such as storage device SD. Volatile media include dynamic memory, such as main memory MM. Transmission media include coaxial cables, copper wire and fiber optics, including the wires that comprise bus BS. Transmission media can also take the form of acoustic or light waves, such as those generated during radio frequency (RF) and infrared (IR) data communications. Computer-readable media can be non-transitory, for example, a floppy disk, a flexible disk, hard disk, magnetic tape, any other magnetic medium, a CD-ROM, DVD, any other optical medium, punch cards, paper tape, any other physical medium with patterns of holes, a RAM, a PROM, and EPROM, a FLASH-EPROM, any other memory chip or cartridge. Non-transitory computer readable media can have instructions recorded thereon. The instructions, when executed by a computer, can implement any of the features described herein. Transitory computer-readable media can include a carrier wave or other propagating electromagnetic signal.

Various forms of computer readable media may be involved in carrying one or more sequences of one or more instructions to processor PRO for execution. For example, the instructions may initially be borne on a magnetic disk of a remote computer. The remote computer can load the instructions into its dynamic memory and send the instructions over a telephone line using a modem. A modem local to computer system CS can receive the data on the telephone line and use an infrared transmitter to convert the data to an infrared signal. An infrared detector coupled to bus BS can receive the data carried in the infrared signal and place the data on bus BS. Bus BS carries the data to main memory MM, from which processor PRO retrieves and executes the instructions. The instructions received by main memory MM may optionally be stored on storage device SD either before or after execution by processor PRO.

Computer system CS may also include a communication interface CI coupled to bus BS. Communication interface CI provides a two-way data communication coupling to a network link NDL that is connected to a local network LAN. For example, communication interface CI may be an integrated service digital network (ISDN) card or a modem to provide a data communication connection to a corresponding type of telephone line. As another example, communication interface CI may be a local area network (LAN) card to provide a data communication connection to a compatible LAN. Wireless links may also be implemented. In any such implementation, communication interface CI sends and receives electrical, electromagnetic or optical signals that carry digital data streams representing various types of information.

Network link NDL typically provides data communication through one or more networks to other data devices. For example, network link NDL may provide a connection through local network LAN to a host computer HC. This can include data communication services provided through the worldwide packet data communication network, now commonly referred to as the “Internet” INT. Local network LAN (Internet) both use electrical, electromagnetic or optical signals that carry digital data streams. The signals through the various networks and the signals on network data link NDL and through communication interface CI, which carry the digital data to and from computer system CS, are exemplary forms of carrier waves transporting the information.

Computer system CS can send messages and receive data, including program code, through the network(s), network data link NDL, and communication interface CI. In the Internet example, host computer HC might transmit a requested code for an application program through Internet INT, network data link NDL, local network LAN and communication interface CI. One such downloaded application may provide all or part of a method described herein, for example. The received code may be executed by processor PRO as it is received, and/or stored in storage device SD, or other non-volatile storage for later execution. In this manner, computer system CS may obtain application code in the form of a carrier wave.

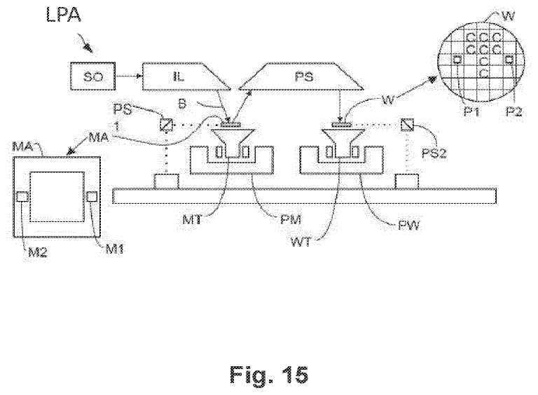

FIG. 15 is a schematic diagram of another lithographic projection apparatus (LPA), according to an embodiment.

LPA can include source collector module SO, illumination system (illuminator) IL configured to condition a radiation beam B (e.g. EUV radiation), support structure MT, substrate table WT, and projection system PS.

Support structure (e.g. a patterning device table) MT can be constructed to support a patterning device (e.g. a mask or a reticle) MA and connected to a first positioner PM configured to accurately position the patterning device;

Substrate table (e.g. a wafer table) WT can be constructed to hold a substrate (e.g. a resist coated wafer) W and connected to a second positioner PW configured to accurately position the substrate.

Projection system (e.g. a reflective projection system) PS can be configured to project a pattern imparted to the radiation beam B by patterning device MA onto a target portion C (e.g. comprising one or more dies) of the substrate W.

As here depicted, LPA can be of a reflective type (e.g. employing a reflective patterning device). It is to be noted that because most materials are absorptive within the EUV wavelength range, the patterning device may have multilayer reflectors comprising, for example, a multi-stack of molybdenum and silicon. In one example, the multi-stack reflector has a 40 layer pairs of molybdenum and silicon where the thickness of each layer is a quarter wavelength. Even smaller wavelengths may be produced with X-ray lithography. Since most material is absorptive at EUV and x-ray wavelengths, a thin piece of patterned absorbing material on the patterning device topography (e.g., a TaN absorber on top of the multi-layer reflector) defines where features would print (positive resist) or not print (negative resist).

Illuminator IL can receive an extreme ultra violet radiation beam from source collector module SO. Methods to produce EUV radiation include, but are not necessarily limited to, converting a material into a plasma state that has at least one element, e.g., xenon, lithium or tin, with one or more emission lines in the EUV range. In one such method, often termed laser produced plasma (“LPP”) the plasma can be produced by irradiating a fuel, such as a droplet, stream or cluster of material having the line-emitting element, with a laser beam. Source collector module SO may be part of an EUV radiation system including a laser, not shown in FIG. 15, for providing the laser beam exciting the fuel. The resulting plasma emits output radiation, e.g., EUV radiation, which is collected using a radiation collector, disposed in the source collector module. The laser and the source collector module may be separate entities, for example when a CO2 laser is used to provide the laser beam for fuel excitation.

In such cases, the laser may not be considered to form part of the lithographic apparatus and the radiation beam can be passed from the laser to the source collector module with the aid of a beam delivery system comprising, for example, suitable directing mirrors and/or a beam expander. In other cases, the source may be an integral part of the source collector module, for example when the source is a discharge produced plasma EUV generator, often termed as a DPP source.

Illuminator IL may comprise an adjuster for adjusting the angular intensity distribution of the radiation beam. Generally, at least the outer and/or inner radial extent (commonly referred to as σ-outer and σ-inner, respectively) of the intensity distribution in a pupil plane of the illuminator can be adjusted. In addition, the illuminator IL may comprise various other components, such as facetted field and pupil mirror devices. The illuminator may be used to condition the radiation beam, to have a desired uniformity and intensity distribution in its cross section.

The radiation beam B can be incident on the patterning device (e.g., mask) MA, which is held on the support structure (e.g., patterning device table) MT, and is patterned by the patterning device. After being reflected from the patterning device (e.g. mask) MA, the radiation beam B passes through the projection system PS, which focuses the beam onto a target portion C of the substrate W. With the aid of the second positioner PW and position sensor PS2 (e.g. an interferometric device, linear encoder or capacitive sensor), the substrate table WT can be moved accurately, e.g. so as to position different target portions C in the path of radiation beam B. Similarly, the first positioner PM and another position sensor PS1 can be used to accurately position the patterning device (e.g. mask) MA with respect to the path of the radiation beam B. Patterning device (e.g. mask) MA and substrate W may be aligned using patterning device alignment marks M1, M2 and substrate alignment marks P1, P2.

The depicted apparatus LPA could be used in at least one of the following modes, step mode, scan mode, and stationary mode.

In step mode, the support structure (e.g. patterning device table) MT and the substrate table WT are kept essentially stationary, while an entire pattern imparted to the radiation beam is projected onto a target portion C at one time (e.g. a single static exposure). The substrate table WT is then shifted in the X and/or Y direction so that a different target portion C can be exposed.

In scan mode, the support structure (e.g. patterning device table) MT and the substrate table WT are scanned synchronously while a pattern imparted to the radiation beam is projected onto target portion C (e.g. a single dynamic exposure). The velocity and direction of substrate table WT relative to the support structure (e.g. patterning device table) MT may be determined by the (de-)magnification and image reversal characteristics of the projection system PS.

In stationary mode, the support structure (e.g. patterning device table) MT is kept essentially stationary holding a programmable patterning device, and substrate table WT is moved or scanned while a pattern imparted to the radiation beam is projected onto a target portion C. In this mode, generally a pulsed radiation source is employed and the programmable patterning device is updated as required after each movement of the substrate table WT or in between successive radiation pulses during a scan. This mode of operation can be readily applied to maskless lithography that utilizes programmable patterning device, such as a programmable mirror array of a type as referred to above.

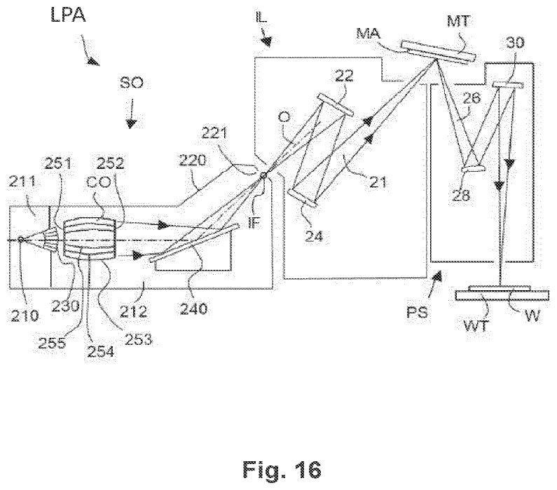

FIG. 16 is a detailed view of the lithographic projection apparatus, according to an embodiment.

As shown, LPA can include the source collector module SO, the illumination system IL, and the projection system PS. The source collector module SO is constructed and arranged such that a vacuum environment can be maintained in an enclosing structure 220 of the source collector module SO. An EUV radiation emitting plasma 210 may be formed by a discharge produced plasma source. EUV radiation may be produced by a gas or vapor, for example Xe gas, Li vapor or Sn vapor in which the very hot plasma 210 is created to emit radiation in the EUV range of the electromagnetic spectrum. The very hot plasma 210 is created by, for example, an electrical discharge causing at least partially ionized plasma. Partial pressures of, for example, 10 Pa of Xe, Li, Sn vapor or any other suitable gas or vapor may be required for efficient generation of the radiation. In an embodiment, a plasma of excited tin (Sn) is provided to produce EUV radiation.

The radiation emitted by the hot plasma 210 is passed from a source chamber 211 into a collector chamber 212 via an optional gas barrier or contaminant trap 230 (in some cases also referred to as contaminant barrier or foil trap) which is positioned in or behind an opening in source chamber 211. The contaminant trap 230 may include a channel structure. Contamination trap 230 may also include a gas barrier or a combination of a gas barrier and a channel structure. The contaminant trap or contaminant barrier 230 further indicated herein at least includes a channel structure, as known in the art.

The collector chamber 211 may include a radiation collector CO which may be a so-called grazing incidence collector. Radiation collector CO has an upstream radiation collector side 251 and a downstream radiation collector side 252. Radiation that traverses collector CO can be reflected off a grating spectral filter 240 to be focused in a virtual source point IF along the optical axis indicated by the dot-dashed line ‘O’. The virtual source point IF is commonly referred to as the intermediate focus, and the source collector module is arranged such that the intermediate focus IF is located at or near an opening 221 in the enclosing structure 220. The virtual source point IF is an image of the radiation emitting plasma 210.

Subsequently the radiation traverses the illumination system IL, which may include a facetted field mirror device 22 and a facetted pupil mirror device 24 arranged to provide a desired angular distribution of the radiation beam 21, at the patterning device MA, as well as a desired uniformity of radiation intensity at the patterning device MA. Upon reflection of the beam of radiation 21 at the patterning device MA, held by the support structure MT, a patterned beam 26 is formed and the patterned beam 26 is imaged by the projection system PS via reflective elements 28, 30 onto a substrate W held by the substrate table WT.

More elements than shown may generally be present in illumination optics unit IL and projection system PS. The grating spectral filter 240 may optionally be present, depending upon the type of lithographic apparatus. Further, there may be more mirrors present than those shown in the figures, for example there may be 1-6 additional reflective elements present in the projection system PS than shown in FIG. 15.

Collector optic CO, as illustrated in FIG. 15, is depicted as a nested collector with grazing incidence reflectors 253, 254 and 255, just as an example of a collector (or collector mirror). The grazing incidence reflectors 253, 254 and 255 are disposed axially symmetric around the optical axis O and a collector optic CO of this type may be used in combination with a discharge produced plasma source, often called a DPP source.

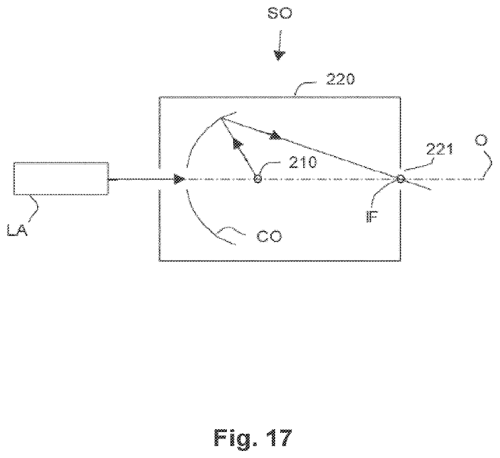

FIG. 17 is a detailed view of source collector module SO of lithographic projection apparatus LPA, according to an embodiment.

Source collector module SO may be part of an LPA radiation system. A laser LA can be arranged to deposit laser energy into a fuel, such as xenon (Xe), tin (Sn) or lithium (Li), creating the highly ionized plasma 210 with electron temperatures of several 10's of eV. The energetic radiation generated during de-excitation and recombination of these ions is emitted from the plasma, collected by a near normal incidence collector optic CO and focused onto the opening 221 in the enclosing structure 220.

The concepts disclosed herein may simulate or mathematically model any generic imaging system for imaging sub wavelength features, and may be especially useful with emerging imaging technologies capable of producing increasingly shorter wavelengths. Emerging technologies already in use include EUV (extreme ultra violet), DUV lithography that is capable of producing a 193 nm wavelength with the use of an ArF laser, and even a 157 nm wavelength with the use of a Fluorine laser. Moreover, EUV lithography is capable of producing wavelengths within a range of 20-50 nm by using a synchrotron or by hitting a material (either solid or a plasma) with high energy electrons in order to produce photons within this range.

While specific embodiments of the disclosure have been described above, it will be appreciated that the disclosure may be practiced otherwise than as described. While the example structures described above as metrology marks are grating structures specifically designed and formed for the purposes of position measurement, in other embodiments, positions may be measured on structures which are functional parts of devices formed on the substrate.

Many devices have regular, grating-like structures. The terms “mark” and “grating structure” as used herein do not require that the structure be provided specifically for the measurement being performed. An opaque layer is not the only kind of overlying structure that may disrupt measurement of the position of the mark by observing the mark in conventional wavelengths. For example, surface roughness, or a conflicting periodic structure, may interfere with measurement at one or more wavelengths.

In association with the position-measuring hardware and suitable structures realized on substrates and patterning devices, an embodiment may include a computer program containing one or more sequences of machine-readable instructions implementing methods of measurement of the type illustrated above to obtain information about the position of the mark covered by an overlying structure.

This computer program may be executed, for example, by a processor or the like which is dedicated to that purpose. There may also be provided a data storage medium (e.g., semiconductor memory, magnetic or optical disk) having such a computer program stored therein.

Although specific reference may have been made above to the use of embodiments of the disclosure in the context of optical lithography, it will be appreciated that the disclosure may be used in other applications, for example, imprint lithography, and where the context allows, is not limited to optical lithography. In imprint lithography, a topography in a patterning device defines the pattern created on a substrate. The topography of the patterning device may be pressed into a layer of resist supplied to the substrate whereupon the resist is cured by applying electromagnetic radiation, heat, pressure or a combination thereof. The patterning device is moved out of the resist leaving a pattern in it after the resist is cured.

The terms “radiation” and “beam” used herein encompass all types of electromagnetic radiation, including ultraviolet (UV) radiation (e.g., having a wavelength of or about 365, 355, 248, 193, 157 or 126 nm) and extreme ultra-violet (EUV) radiation (e.g., having a wavelength in the range of 1-100 nm), as well as particle beams, such as ion beams or electron beams.

The term “lens,” where the context allows, may refer to any one or a combination of various types of optical components, including refractive, reflective, magnetic, electromagnetic and electrostatic optical components. Reflective components are likely to be used in an apparatus operating in the UV and/or EUV ranges.

Embodiments of the present disclosure can be further described by the following clauses.

1. A non-transitory computer-readable medium for generating a metrology mark structure on a chip for measuring overlay characteristics induced by semiconductor manufacturing processes performed on the chip by determining features for the metrology mark structure based on a pattern distribution, the medium comprising instructions stored therein that, when executed by one or more processors, cause operations comprising:
receiving a first function that characterizes an overlay fingerprint induced by semiconductor manufacturing processes performed on a substrate, the overlay fingerprint being a representation of an overlay between features on a first layer relative to features on a second layer of the substrate;
receiving a second function that characterizes a physical effect of a process of the semiconductor manufacturing processes on a layer of the substrate;
determining, by applying a deconvolving operation between the first function and the second function, a pattern distribution for the first layer, the pattern distribution indicative of a density of features within a portion of the first layer; and
generating, based on the pattern distribution, shapes and/or positioning of the features of the metrology mark structure.
   2. The medium of clause 1, wherein:
the features of the metrology mark structure are non-uniformly distributed on the first layer causing a density of features in one portion of the metrology structure to be greater than a density of features in another portion of the metrology structure, and
the features on the second layer are uniformly distributed on the second layer, the second layer formed below the first layer, wherein uniformly distributed features have a uniform spacing between the features on the second layer.
   3. A non-transitory computer-readable medium for determining a metrology mark structure for measuring process characteristics of a semiconductor manufacturing process comprising instructions stored therein that, when executed by one or more processors, cause operations comprising:
obtaining a first function configured to characterize an overlay fingerprint induced by a semiconductor manufacturing process performed on a substrate;
deriving, based on the first function, a pattern distribution indicative of a number of features within a portion of the substrate; and
determining, based on the pattern distribution, physical characteristics of the features of the metrology mark structure for disposing on the substrate.
   4. The medium of clause 3, wherein the obtaining of the first function comprises:
obtaining a differentiable function whose gradient is equivalent to the overlay fingerprint induced by the semiconductor manufacturing process.
   5. The medium of any of clauses 3-4, wherein the first function comprises at least one of:
a parabolic function of one or more dimensions of the substrate;
a trigonometric function of one or more dimensions of the substrate; or
an inverse function of one or more dimensions of the substrate.
   6. The medium of any of clauses 3-5, wherein the deriving of the pattern distribution comprises:
deconvolving the first function using a second function, the second function characterizing a physical effect of the semiconductor manufacturing process on a layer of the substrate.
   7. The medium of clause 6, wherein the second function is separable upon convolving with the pattern distribution.
   8. The medium of clause 6, wherein the second function comprises a kernel function which is a function of a length dimension of the substrate allowing the second function to capture changes in the overlay fingerprint at different lengths on the substrate.
   9. The medium of clause 8, wherein the kernel function is a Gaussian kernel having a length as a parameter
   10. The medium of any of clauses 6-9, wherein the second function comprises at least one of:
a diffusion kernel characterizing a redistribution of surface charges during an etching process that contributes to the overlay fingerprint; or
a stress kernel characterizing a stress released during an etching process that contributes to the overlay fingerprint.
   11. The medium of any of clauses 6-10, wherein the deriving of the pattern distribution comprises:
applying a Fourier transform to the first function and the second function to obtain a transformed first function and a transformed second function;
dividing the transformed first function by the transformed second function; and
subsequently applying an inverse Fourier transform to determine the pattern distribution of the metrology mark structure.
   12. The medium of any of clauses 3-10, wherein determining physical characteristics of the features comprises:
determining a set of polygon shapes of the metrology mark structure based on the pattern distribution, a first set of polygon shapes comprises polygon shapes distinct from polygon shapes of a second set of polygon shapes; and/or
determining positioning of the features relative to each other.
   13. The medium of clause 12, wherein determining the physical characteristics of the features comprises:
determining, based on a set of geometric constraints and the pattern distribution, the set of polygon shapes of the metrology mark structure; and
determining, based on distance constraints between the features and the pattern distribution, a positioning between polygon shapes of the first set of polygon shapes or the second set of polygon shapes.
   14. The medium of clause 13, wherein the set of geometric constraints comprising a set of threshold values related to shape, size, and/or relative positioning of polygon shapes with respect to each other.
   15. The medium of clause 13, wherein determining the physical characteristics of the features is an iterative process, each iteration comprising:
distributing, based on the pattern distribution, an initial set of polygon shapes within a portion of the metrology mark structure;
determining whether the set of geometric constraints associated with the initial set of polygon shapes are satisfied;
responsive to one or more geometric constraints not being satisfied, modifying a shape of one or more polygon shapes of the initial set of polygon shapes causing the one or more geometric constraints to be satisfied; and
including the modified polygon shapes in a set of the set of polygon shapes.
   16. The medium of any of clauses 3-15, further comprises:
obtaining measurement of an overlay of a patterned substrate at the metrology mark structure;
predicting an overlay fingerprint using a pattern density function associated with the metrology mark structure and a set of second functions characterizing physical effects of a set of processes performed on the patterned substrate; and
determining, based on the measured overlay and the predicted overlay fingerprint, an overlay fingerprint contribution of each of the set of processes performed on the patterned substrate.
   17. The medium of clause 16, wherein determining the overlay fingerprint contribution comprises:
performing, by tuning parameters associated with the set of second functions, a multilinear regression to fit the predicted overlay fingerprint to the measured overlay.
   18. The medium of clause 17, further comprising:
adjusting, based on an overlay fingerprint contribution of a process obtained after the multilinear regression, process parameters of the set of processes to reduce the overlay fingerprint contribution associated with the process.
   19. The medium of any of clauses 16, further comprises:
separating a diffusion fingerprint and a stress fingerprint from the measured overlay fingerprint of the metrology mark structure by measuring an overlay response of the second function on the metrology mark structure.
   20. The medium of any of clauses 16-19, further comprising:
extrapolating, using the set of second functions, the measured overlay to an entire field of the substrate.
   21. The medium of clause 20, further comprising:
calibrating one or more process models using the extrapolated overlay of the entire field of the substrate, and
determining, based on the calibrated process models, parameter values of a process for controlling the overlay induced by the process.
   22. The medium of any of clauses 3-21, wherein the overlay fingerprint is a representation of an overlay between features on a first layer relative to features on a second layer of the substrate.
   23. The medium of clause 22, wherein the metrology mark structure is formed on a first layer of the substrate.
   24. The medium of clauses 23, wherein features of the metrology mark structure on the first layer have a non-periodic structure, and features on the second layer have period structure.
   25. A method for determining a metrology mark structure, the method comprising:
obtaining a first function to characterize an overlay fingerprint induced by a semiconductor manufacturing process performed on a substrate;
deriving, based on the first function, a pattern distribution indicative of a number of features within a portion of the substrate; and
determining, based on the pattern distribution, physical characteristics of the features of the metrology mark structure for disposing on the substrate.
   26. The method of clause 25, wherein the obtaining of the first function comprises:
obtaining a differentiable function whose gradient is equivalent to the overlay fingerprint induced by the semiconductor manufacturing process.
   27. The method of any of clauses 25-26, wherein the first function comprises at least one of:
a parabolic function of one or more dimensions of the substrate;
a trigonometric function of one or more dimensions of the substrate; or
an inverse function of one or more dimensions of the substrate.
   28. The method of any of clauses 25-27, wherein the deriving of the pattern distribution comprises:
deconvolving the first function using a second function, the second function characterizing a physical effect of the semiconductor manufacturing process on a layer of the substrate.
   29. The method of clause 28, wherein the second function is separable upon convolving with the pattern distribution.
   30. The method of clause 28, wherein the second function comprises a kernel function which is a function of a length dimension of the substrate allowing the second function to capture changes in the overlay fingerprint at different lengths on the substrate.
   31. The method of clause 30, wherein the kernel function is a Gaussian kernel having a length as a parameter.
   32. The method of any of clauses 28-31, wherein the second function comprises at least one of:
a diffusion kernel characterizing a redistribution of surface charges during an etching process that contributes to the overlay fingerprint; or
a stress kernel characterizing a stress released during an etching process that contributes to the overlay fingerprint.
   33. The method of any of clauses 28-32, wherein the deriving of the pattern distribution comprises:
applying a Fourier transform to the first function and the second function to obtain a transformed first function and a transformed second function;
dividing the transformed first function by the transformed second function; and
subsequently applying an inverse Fourier transform to determine the pattern distribution of the metrology mark structure.
   34. The method of any of clauses 25-33, wherein determining physical characteristics of the features comprises:
determining a set of polygon shapes of the metrology mark structure based on the pattern distribution, a first set of polygon shapes comprises polygon shapes distinct from polygon shapes of a second set of polygon shapes; and/or
determining positioning of the features relative to each other.
   35. The method of clause 34, wherein determining the physical characteristics of the features comprises:
determining, based on a set of geometric constraints and the pattern distribution, the set of polygon shapes of the metrology mark structure; and
determining, based on distance constraints between the features and the pattern distribution, a positioning between polygon shapes of the first set of polygon shapes or the second set of polygon shapes.
   36. The method of clause 35, wherein the set of geometric constraints comprising a set of threshold values related to shape, size, and/or relative positioning of polygon shapes with respect to each other.
   37. The method of clause 35, wherein determining the physical characteristics of the features is an iterative process, each iteration comprising:
distributing, based on the pattern distribution, an initial set of polygon shapes within a portion of the metrology mark structure;
determining whether the set of geometric constraints associated with the initial set of polygon shapes are satisfied;
responsive to one or more geometric constraints not being satisfied, modifying a shape of one or more polygon shapes of the initial set of polygon shapes causing the one or more geometric constraints to be satisfied; and
including the modified polygon shapes in a set of the set of polygon shapes.
   38. The method of any of clauses 25-37, further comprises:
obtaining measurement of an overlay of a patterned substrate at the metrology mark structure;
predicting an overlay fingerprint using a pattern density function associated with the metrology mark structure and a set of second functions characterizing physical effects of a set of processes performed on the patterned substrate; and
determining, based on the measured overlay and the predicted overlay fingerprint, an overlay fingerprint contribution of each of the set of processes performed on the patterned substrate.
   39. The method of clause 38, wherein determining the overlay fingerprint contribution comprises:
performing, by tuning parameters associated with the set of second functions, a multilinear regression to fit the predicted overlay fingerprint to the measured overlay.
   40. The method of clause 39, further comprising:
adjusting, based on an overlay fingerprint contribution of a process obtained after the multilinear regression, process parameters of the set of processes to reduce the overlay fingerprint contribution associated with the process.
   41. The method of any of clauses 38, further comprises:
separating a diffusion fingerprint and a stress fingerprint from the measured overlay fingerprint of the metrology mark structure by measuring an overlay response of the second function on the metrology mark structure.
   42. The method of any of clauses 38-41, further comprising:
extrapolating, using the set of second functions, the measured overlay to an entire field of the substrate.
   43. The method of clause 42, further comprising:
calibrating one or more process models using the extrapolated overlay of the entire field of the substrate, and
determining, based on the calibrated process models, parameter values of a process for controlling the overlay induced by the process.
   44. The method of any of clauses 25-43, wherein the overlay fingerprint is a representation of an overlay between features on a first layer relative to features on a second layer of the substrate.
   45. The method of clause 44, wherein the metrology mark structure is formed on a first layer.
   46. The method of clause 45, wherein features of the metrology mark structure on the first layer have a non-periodic structure, and features on the second layer have period structure.
   47. A non-transitory computer-readable medium, the medium comprising instructions stored therein that, when executed by one or more processors, cause operations of a method of clauses 25-46.

The breadth and scope of the present disclosure should not be limited by any of the above described exemplary embodiments, but should be defined only in accordance with the following claims and their equivalents.

While the concepts disclosed herein may be used on a substrate such as a silicon wafer, it shall be understood that the disclosed concepts may be used with any type of lithographic systems, e.g., those used for imaging on substrates other than silicon wafers.

The descriptions above are intended to be illustrative, not limiting. Thus, it will be apparent to one skilled in the art that modifications may be made as described without departing from the scope of the claims set out below.

1. A non-transitory computer-readable medium, the medium comprising instructions stored therein that, when executed by one or more processors, cause the one or more processors to at least:
obtain a first function to characterize an overlay fingerprint induced by a semiconductor manufacturing process performed on a substrate;
derive, based on the first function, a pattern distribution indicative of a number of features within a portion of the substrate; and
determine, based on the pattern distribution, one or more physical characteristics of features of the metrology mark structure for disposing on the substrate.

2. The medium of claim 1, wherein the instructions configured to cause the one or more processors to obtain the first function are further configured to cause the one or more processors to obtain a differentiable function whose gradient is equivalent to the overlay fingerprint induced by the semiconductor manufacturing process.

3. The medium of claim 1, wherein the first function comprises at least one selected from:
a parabolic function of one or more dimensions of the substrate;
a trigonometric function of one or more dimensions of the substrate; or
an inverse function of one or more dimensions of the substrate.

4. The medium of claim 1, wherein the instructions configured to cause the one or more processors to derive the pattern distribution are further configured to cause the one or more processors to deconvolve the first function using a second function, the second function characterizing a physical effect of the semiconductor manufacturing process on a layer of the substrate.

5. The medium of claim 4, wherein the second function comprises a kernel function which is a function of a length dimension of the substrate allowing the second function to capture changes in the overlay fingerprint at different lengths on the substrate.

6. The medium of claim 5, wherein the second function comprises at least one selected from:
a diffusion kernel characterizing a redistribution of surface charges during an etching process that contributes to the overlay fingerprint; or
a stress kernel characterizing a stress released during an etching process that contributes to the overlay fingerprint.

7. The medium of claim 4, wherein the instructions configured to cause the one or more processors to derive the pattern distribution are further configured to cause the one or more processors to:
apply a Fourier transform to the first function and the second function to obtain a transformed first function and a transformed second function;
divide the transformed first function by the transformed second function; and
subsequently apply an inverse Fourier transform to determine the pattern distribution of the metrology mark structure.

8. The medium of claim 1, wherein the instructions configured to cause the one or more processors to determine physical characteristics of the features are further configured to cause the one or more processors to:
determine a set of polygon shapes of the metrology mark structure based on the pattern distribution, a first set of polygon shapes comprises polygon shapes distinct from polygon shapes of a second set of polygon shapes; and/or
determine positioning of the features relative to each other.

9. The medium of claim 1, wherein the instructions configured to cause the one or more processors to determine the physical characteristics of the features are further configured to cause the one or more processors to:
determine, based on a set of geometric constraints and the pattern distribution, a set of polygon shapes of the metrology mark structure; and
determine, based on distance constraints between the features and the pattern distribution, a positioning between polygon shapes of a set of polygon shapes.

10. The medium of claim 1, wherein the instructions configured to cause the one or more processors to determine the physical characteristics of the features are further configured are further configured to cause the one or more processors to:
distribute, based on the pattern distribution, an initial set of polygon shapes within a portion of the metrology mark structure;
determine whether a set of geometric constraints associated with the initial set of polygon shapes are satisfied;
responsive to one or more geometric constraints not being satisfied, modify a shape of one or more polygon shapes of the initial set of polygon shapes causing the one or more geometric constraints to be satisfied; and
include the modified polygon shapes in a set of polygon shapes.

11. The medium of claim 1, wherein the instructions are further configured to cause the one or more processors to:
obtain measurement of an overlay of a patterned substrate at the metrology mark structure;
predict an overlay fingerprint using a pattern density function associated with the metrology mark structure and a set of functions characterizing physical effects of a set of processes performed on the patterned substrate; and
determine, based on the measured overlay and the predicted overlay fingerprint, an overlay fingerprint contribution of each of the set of processes performed on the patterned substrate.

12. The medium of claim 11, wherein the instructions configured to cause the one or more processors to determine the overlay fingerprint contribution are further configured to cause the one or more processors to:
perform, by tuning one or more parameters associated with the set of functions, a multilinear regression to fit the predicted overlay fingerprint to the measured overlay; and
adjust, based on an overlay fingerprint contribution of a process obtained after the multilinear regression, one or more process parameters of the set of processes to reduce the overlay fingerprint contribution associated with the semiconductor manufacturing process.

13. The medium of claim 11, wherein the instructions are further configured to cause the one or more processors to separate a diffusion fingerprint and a stress fingerprint from the measured overlay fingerprint of the metrology mark structure by measurement of an overlay response of at one function of the set of functions on the metrology mark structure.

14. The medium of claim 13, wherein the instructions are further configured to cause the one or more processors to:
extrapolate, using the set of functions, the measured overlay to an entire field of the substrate;
calibrate one or more process models using the extrapolated overlay of the entire field of the substrate, and
determine, based on the calibrated one or more process models, one or more parameter values of a process for controlling the overlay induced by the semiconductor manufacturing process.

15. The medium of claim 1, wherein the overlay fingerprint is a representation of an overlay between features on a first layer relative to features on a second layer of the substrate.

16. The medium of claim 15, wherein features of the metrology mark structure on the first layer have a non-periodic structure, and features of the metrology mark structure on the second layer have a periodic structure.

17. A non-transitory computer-readable medium comprising instructions therein, the instructions, when executed by one or more processors, are configured to cause the one or more processors to at least:
obtain a first function that characterizes an overlay fingerprint induced by semiconductor manufacturing processes performed on a substrate, the overlay fingerprint being a representation of an overlay between features on a first layer of the substrate and features on a second layer of the substrate;
obtain a second function that characterizes a physical effect of a process of the semiconductor manufacturing processes on the substrate;
determine, by application of a deconvolving operation between the first function and the second function, a pattern distribution for the first layer, the pattern distribution indicative of a density of features within a portion of the first layer; and
generate, based on the pattern distribution, a shape and/or positioning of one or more features of a metrology mark structure for measuring overlay characteristics induced by the semiconductor manufacturing processes.

18. The medium of claim 17, wherein:
features are non-uniformly distributed on the first layer causing a density of features in one portion of the metrology structure to be greater than a density of features in another portion of the metrology structure, and
features are uniformly distributed on the second layer, the second layer formed below the first layer, wherein uniformly distributed features have a uniform spacing between the features on the second layer.

19. The medium of claim 17, wherein the second function comprises:
a kernel function which is a function of a length dimension of the substrate allowing the second function to capture changes in the overlay fingerprint at different lengths on the substrate;
a diffusion kernel characterizing a redistribution of surface charges during an etching process that contributes to the overlay fingerprint; or
a stress kernel characterizing a stress released during an etching process that contributes to the overlay fingerprint.

20. The medium of claim 17, wherein the first function comprises at least one selected from:
a parabolic function of one or more dimensions of the substrate;
a trigonometric function of one or more dimensions of the substrate; or
an inverse function of one or more dimensions of the substrate.
